(19) United States
(12) Patent Application Publication
(10) Pub. No.: US 2026/0138865 A1
(43) Pub. Date: May 21, 2026

(54) BUMPSTOP PROCESS FOR A MOTION SENSOR

(71) Applicant: InvenSense, Inc., San Jose, CA (US)

(72) Inventors: Daesung Lee, San Jose, CA (US); Salman Akram, San Jose, CA (US); Carrie Low, Union City, CA (US); Alan Cuthbertson, San Jose, CA (US)

(21) Appl. No.: 19/393,159

(22) Filed: Nov. 18, 2025

Related U.S. Application Data
(60) Provisional application No. 63/722,516, filed on Nov. 19, 2024.

(51) Int. Cl. B81B 3/00; B81C 1/00

(52) U.S. Cl. CPC B81B 3/0051; B81C 1/00523

(57) ABSTRACT

A method includes etching a portion of an oxide layer of a substrate to form a step shape on the oxide layer. The step shape is associated with a location of a bumpstop. The substrate comprises the oxide layer and a passivation layer formed over an intermetal dielectric (IMD) layer and a plurality of stacked metal layers. A via is etched within the step shape of the substrate to expose a metal layer within the plurality of stacked metal layers. A metal adhesion layer is formed over the oxide layer and within the via. The method includes forming a top metal layer over the metal adhesion layer. The method further includes patterning the metal adhesion layer and the top metal layer to maintain the top metal layer and the metal adhesion layer within the via, and the step shape formed in the oxide layer, to form the bumpstop.

### CROSS-REFERENCE TO RELATED APPLICATIONS

This application is a Non-Provisional Patent Application that claims the benefit and priority to the provisional Patent Application No. 63/722,516 , which was filed on Nov. 19, 2024, which is incorporated herein by reference in its entirety.

### BACKGROUND

MEMS (“micro-electro-mechanical systems”) are a class of devices that are fabricated using semiconductor-like processes and exhibit mechanical characteristics. For example, MEMS devices may include the ability to move or deform. In many cases, but not always, MEMS interact with electrical signals. A MEMS device may refer to a semiconductor device that is implemented as a micro-electro-mechanical system. A MEMS device includes mechanical elements and may optionally include electronics (e.g., electronics for sensing). MEMS devices include but are not limited to, for example, gyroscopes, accelerometers, magnetometers, pressure sensors, microphone, etc.

MEMS devices may be coupled to a substrate, e.g., a complementary metal-oxide-semiconductor (CMOS). MEMS devices include a proof-mass in an actuator layer (also referred to as the device layer) that moves in response to a stimuli, e.g., motion, etc. A bumpstop may be used to limit the displacement of a proof-mass to meet the robustness requirement. Additionally, to discharge electrostatic charges of proof-mass, the bumpstop may be coated with a layer of conductive material. In general, contact material, surface topography, and the condition of the bumpstop and the proof-mass impact the performance of the sensor, e.g., stiction (stickiness between two components may be referred as stiction), offset stability, robustness, etc. Conductive layer generally does not bond well with the underlying material that the bumpstop is made of, e.g., passivation layer, oxide layer, etc. As such, an adhesion layer may be used as a middle layer to bond the conductive layer to the passivation/oxide layer of the bumpstop. Unfortunately, imperfection etching process during formation of the bumpstop may result in the vertical walls of the bumpstop being slanted (at an angle), thereby exposing the adhesion layer that causes stiction when the proof-mass becomes in contact with the adhesion layer.

### SUMMARY

Accordingly, a need has arisen to create a bumpstop with a conductive layer where exposure of the adhesion layer of the bumpstop to the proof-mass (device layer) is reduced in order to reduce stiction when the proof-mass becomes in contact with bumpstop. The embodiments form bumpstops in such a manner to reduce stiction and to improve offset stability.

A method includes etching a portion of an oxide layer of a substrate to form a step shape on the oxide layer, wherein the step shape is associated with a location of a bumpstop. The substrate comprises the oxide layer and a passivation layer formed over an intermetal dielectric (IMD) layer and a plurality of stacked metal layers. The method also includes etching a via within the step shape of the substrate to expose a metal layer within the plurality of stacked metal layers. In one nonlimiting example, the method includes forming a metal adhesion layer over the oxide layer and within the via. It is appreciated that a top metal layer may be formed over the metal adhesion layer. The method also includes patterning the metal adhesion layer and the top metal layer to maintain the top metal layer and the metal adhesion layer within the via, and the step shape formed in the oxide layer, to form the bumpstop.

According to some embodiments, the patterning further comprises patterning to retain the metal adhesion layer and top metal layer over the vertical side wall of the step shape. In one nonlimiting example, the patterning further comprises exposing a portion of the oxide layer on the bumpstop. In one nonlimiting example, the method further includes etching the exposed oxide layer to form a second step shape.

In some embodiments, the metal adhesion layer is selected from a group consisting of Titanium (Ti), Tantalum (Ta), and chromium. In one nonlimiting example, the top metal layer is selected from a group consisting of Titanium Nitride (TiN), Titanium Tungsten (TiW), and Tantalum Nitride (TaN).

In some embodiments, the method further includes etching a second portion of the substrate to expose an outgassing layer within the oxide layer. In one nonlimiting example, the etching the portion of the oxide layer of a substrate further includes etching the oxide layer over the second portion of the substrate and retain a portion of the oxide layer over the outgassing layer.

In one nonlimiting example, the method further includes etching a third portion of the substrate to expose a second plurality of stacked metal layers. In one nonlimiting example, the method includes forming a dimple pattern in the oxide layer prior to etching the via. In some embodiments, the method further includes forming the metal adhesion layer and the top metal layers conforming the dimple pattern. In some embodiments, the method further includes forming the metal adhesion layer and the top metal layers conforming the dimple pattern.

In some embodiments, a device may include a substrate comprising an oxide layer, a passivation layer and an intermetal dielectric (IMD) layer. The device may further include a first region of the substrate is associated with a bumpstop. The bumpstop includes a step in the oxide layer. In one nonlimiting example, the bumpstop includes a via formed within the oxide layer and further within the passivation layer and reaches a metal layer of a plurality of stacked metal layers. In one nonlimiting example a metal adhesion layer is formed over a horizontal portion of the oxide layer and further within the via. In some embodiments a top metal layer is formed over the metal adhesion layer.

According to some embodiments, the metal-adhesion layer and the top metal layer cover the vertical side wall of the step. In some embodiments, the metal-adhesion layer and the top metal layer cover a lowers horizontal layer of the step. In one nonlimiting example, the device further includes a second step in the oxide layer in the outer periphery of the bumpstop.

In some embodiments, the metal adhesion layer is selected from a group consisting of Titanium (Ti), Tantalum (Ta), and chromium. In one nonlimiting example, the top metal layer is selected from a group consisting of Titanium Nitride (TiN), Titanium Tungsten (TiW), and Tantalum Nitride (TaN).

In some embodiments, a top surface of the oxide layer of the bumpstop has a plurality of dimples. It is appreciated that the metal-adhesion layer and the top metal layer trace contours of the plurality of dimples.

In some embodiments, the device includes a second region of the substrate, wherein an outgassing layer is disposed within the oxide layer. In one nonlimiting example, a second plurality of stacked metal layers is disposed over the passivation layer in the third region.

These and other features and advantages will be apparent from a reading of the following detailed description.

### BRIEF DESCRIPTION OF DRAWINGS

FIG. 1 shows an example of imperfection bumpstop and an actuator.

FIGS. 2A-2B show formation of a bumpstop according to one aspect of the present embodiments.

FIGS. 3A-3L show a process of forming a bumpstop according to one aspect of the present embodiments.

FIGS. 4A-4H show another process of forming another bumpstop according to one aspect of the present embodiments.

FIGS. 5A-5J show yet another process of forming yet another bumpstop according to one aspect of the present embodiments.

FIGS. 6A-6G show even another process of forming a bumpstop according to one aspect of the present embodiments.

FIG. 7 shows a sensing device with a bumpstop with reduced stiction according to one aspect of the present embodiments.

FIG. 8 shows a flow diagram for forming a bumpstop according to one aspect of the present embodiments.

### DESCRIPTION

Before various embodiments are described in greater detail, it should be understood that the embodiments are not limiting, as elements in such embodiments may vary. It should likewise be understood that a particular embodiment described and/or illustrated herein has elements which may be readily separated from the particular embodiment and optionally combined with any of several other embodiments or substituted for elements in any of several other embodiments described herein.

It should also be understood that the terminology used herein is for the purpose of describing certain concepts, and the terminology is not intended to be limiting. Unless defined otherwise, all technical and scientific terms used herein have the same meaning as commonly understood in the art to which the embodiments pertain.

Unless indicated otherwise, ordinal numbers (e.g., first, second, third, etc.) are used to distinguish or identify different elements or steps in a group of elements or steps, and do not supply a serial or numerical limitation on the elements or steps of the embodiments thereof. For example, “first,” “second,” and “third” elements or steps need not necessarily appear in that order, and the embodiments thereof need not necessarily be limited to three elements or steps. It should also be understood that, unless indicated otherwise, any labels such as “left,” “right,” “front,” “back,” “top,” “middle,” “bottom,” “beside,” “forward,” “reverse,” “overlying,” “underlying,” “up,” “down,” or other similar terms such as “upper,” “lower,” “above,” “below,” “under,” “between,” “over,” “vertical,” “horizontal,” “proximal,” “distal,” and the like are used for convenience and are not intended to imply, for example, any particular fixed location, orientation, or direction. Instead, such labels are used to reflect, for example, relative location, orientation, or directions. It should also be understood that the singular forms of “a,” “an,” and “the” include plural references unless the context clearly dictates otherwise.

Terms such as “over,” “overlying,” “above,” “under,” etc. are understood to refer to elements that may be in direct contact or may have other elements in-between. For example, two layers may be in overlying contact, wherein one layer is over another layer and the two layers physically contact. In another example, two layers may be separated by one or more layers, wherein a first layer is over a second layer and one or more intermediate layers are between the first and second layers, such that the first and second layers do not physically contact.

It is appreciated that the embodiments are described with respect to MEMS coupled to a CMOS wafer for illustrative purposes and should not be construed as limiting the scope of the embodiments. A conductive layer, e.g., Titanium Nitride (TiN), Titanium Tungsten (TiW), Tantalum Nitride (TaN), etc., may be deposited over an adhesion layer, e.g., Titanium (Ti), Tantalum (Ta), chromium, etc., which may be deposited over a bumpstop material being formed on a CMOS wafer. In general, the amount of oxidation of the conductive layer may be affected by the presence of available adhesion layer on the bumpstop surface. For example, increase in adhesion layer liner may increase the amount of surface oxidation. It is appreciated that the oxidation of the bumpstop may also be impacted due to moisture outgassing from the passivation layer and the intermetal dielectric (IMD) layer, e.g., SiO₂, SiN, etc.

According to some embodiments, in order to reduce stiction resulting from the proof-mass contacting the adhesion layer, the bumpstop is formed as a step-shaped (hereinafter step). Thus, the proof-mass does not contact the adhesion layer even in presence of imperfections resulting from the etching process by forming a step to create space between the proof-mass and the adhesion layer.

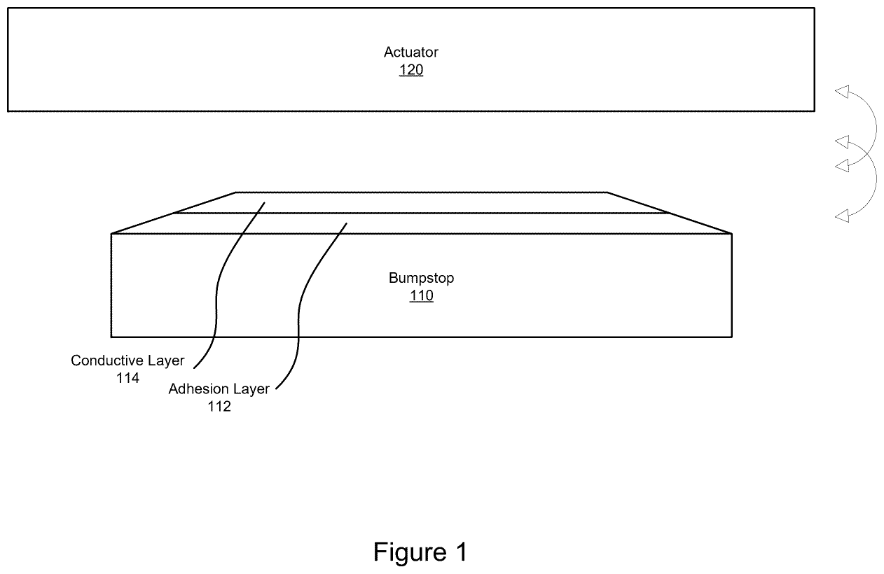

FIG. 1 shows an example of imperfection bumpstop and an actuator. The MEMS device layer may commonly be referred to as the actuator 120 with movable structures, e.g., proof mass, etc. The bumpstop 110 may be formed from a combination of passivation layer, oxide layer, etc. As described above, in order to discharge electrostatic charges of the proof-mass, a top layer of the bumpstop 110 may be coated with a conductive layer 114. However, as described above, the conductive layer 114 may not adhere well to the bumpstop 110. As such, an adhesion layer 112 may be used to bond the conductive layer 114 to the bumpstop 110. As illustrated, the edges of the conductive layer 114 and the adhesive layer 112 become slanted due to imperfection in etching process as opposed to being (ideally) vertical. Thus, when the movable part of the actuator 120 moves (e.g., rotates) it may become in contact with the adhesion layer 112. The adhesion layer 112 increases stiction when the actuator 120 becomes in contact with it, thereby resulting in inferior performance (increasing stiction, increasing offset instability, etc.).

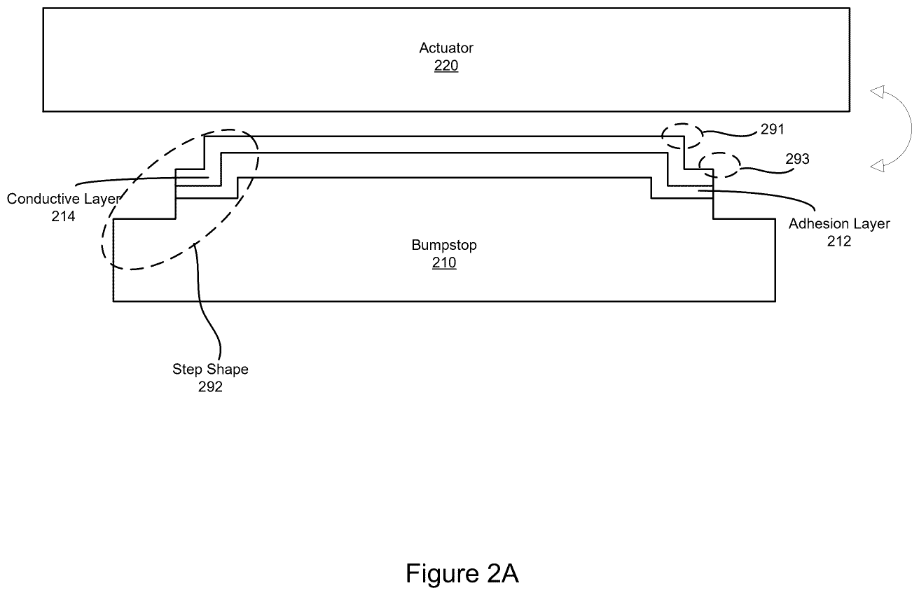

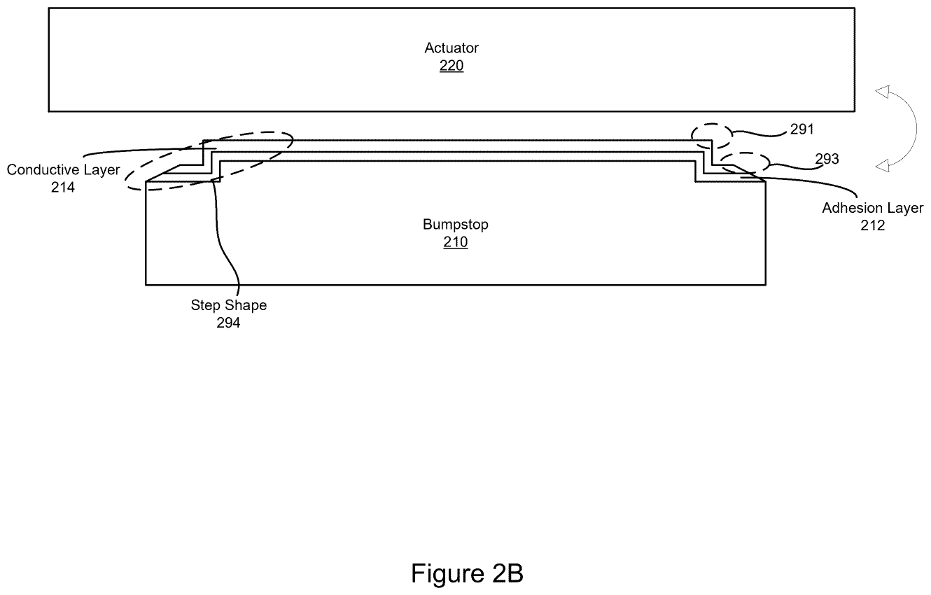

FIGS. 2A-2B show formation of a bumpstop according to one aspect of the present embodiments. In FIG. 2A, a bumpstop 210 may be formed where its edges have a step shape 292, as illustrated. In one nonlimiting example, two steps may be formed, as shown for illustrative purposes and should not be construed as limiting the scope of the embodiments. For example, one step may be formed instead or more than two steps may be formed. In this example, an adhesion layer 212 may be formed directly over the bumpstop 210 to aid in adhering a conductive layer 214 to the bumpstop 210. The step shape 292 covered with the conductive layer 214 and adhesion layer 212 prevents the actuator 220 (similar to actuator 120) from making contact with location 293 (where the adhesion layer 212 may be exposed causing stiction) because location 291 restricts the actuator 220 from further movement preventing it from making contact with the vertical wall of the adhesin layer 212 that may be exposed. FIG. 2B is similar to FIG. 2A except that the step shape 292 having two steps is replaced with one step, as illustrated. In other words, the bumpstop 210 has a step shape 294. As described above, imperfections during the etching process may result in the edges (of the conductive layer 214 and adhesion layer 212) not to be straight but rather at an angle. Stiction will result if the actuator 220 moves and makes contact with the adhesion layer 212. However, the step shape 294 results in the actuator 220 making contact at location 291, thereby preventing the actuator 220 from making contact with the exposed portion of the adhesion layer 212 that causes stiction. In the described embodiments, adhesion layer 212 comprises a conductive material.

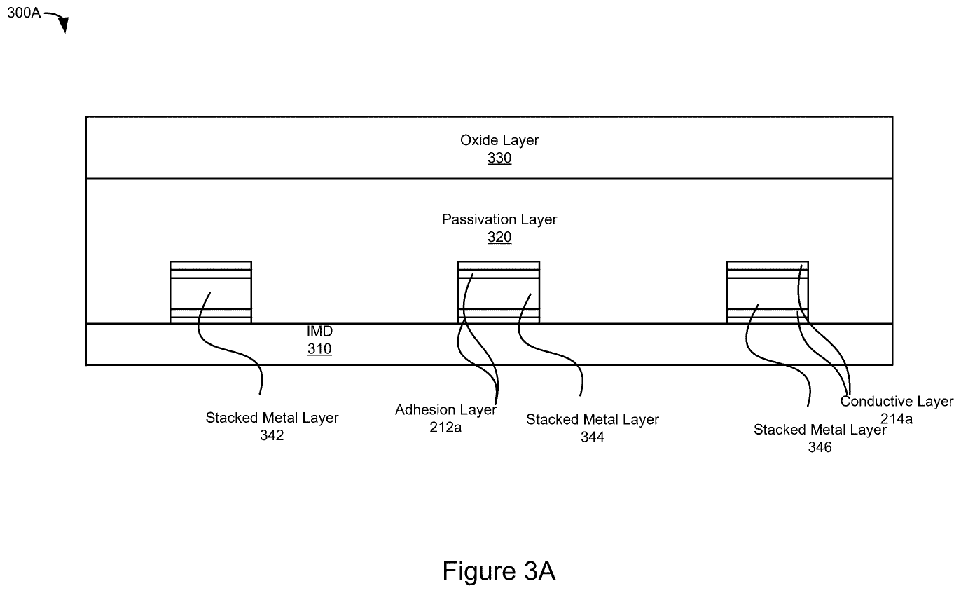

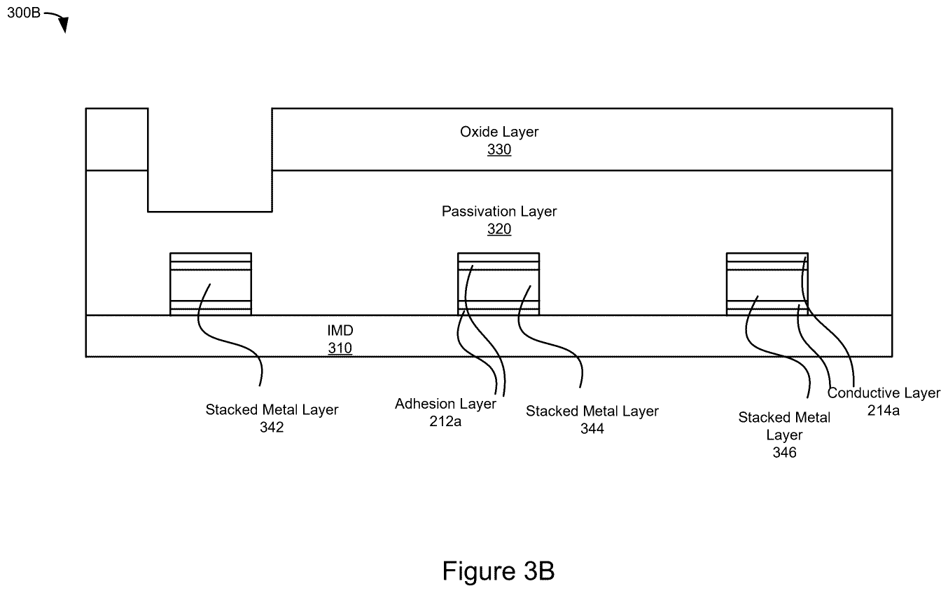

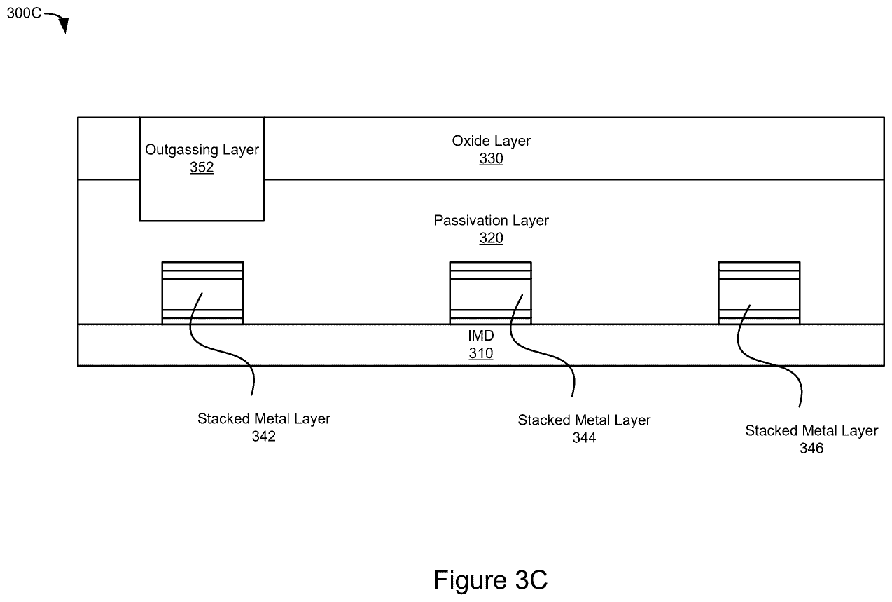

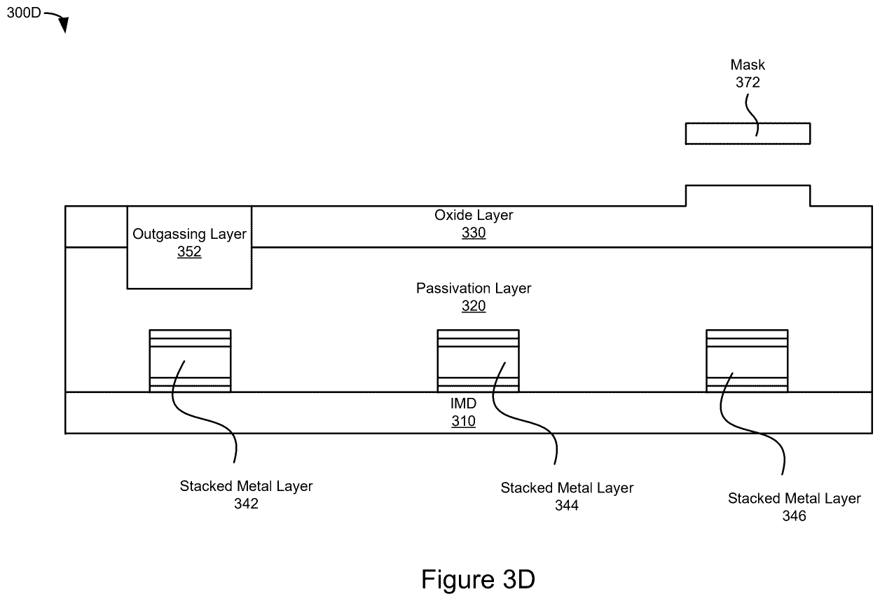

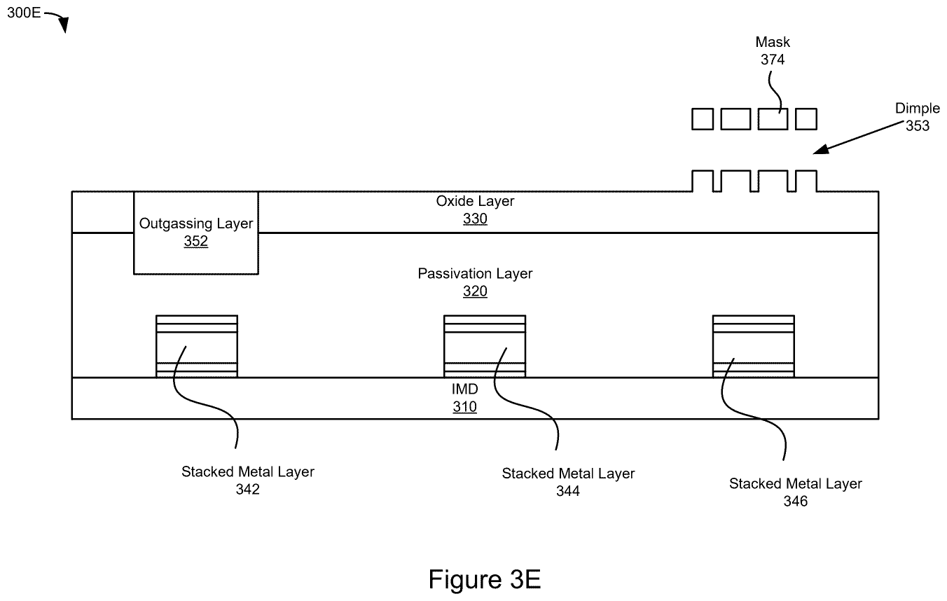

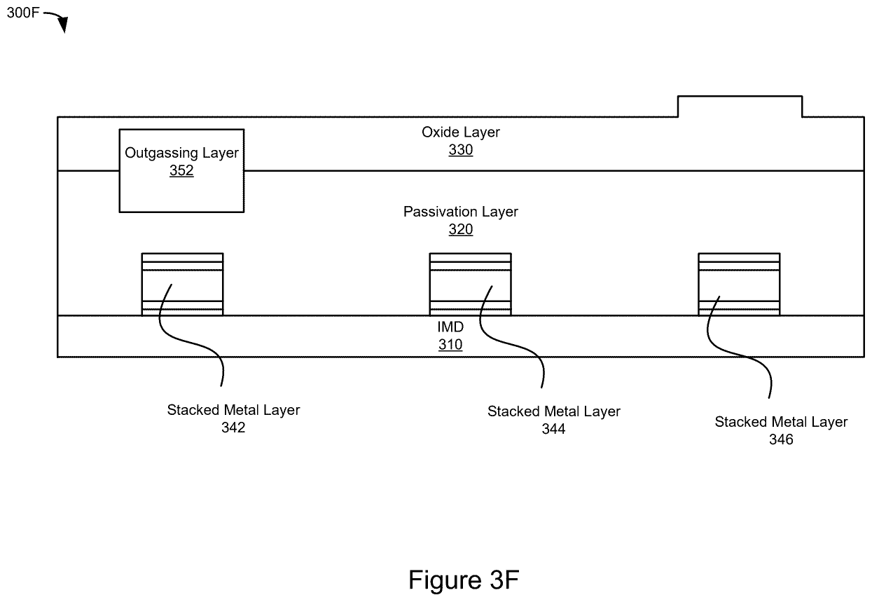

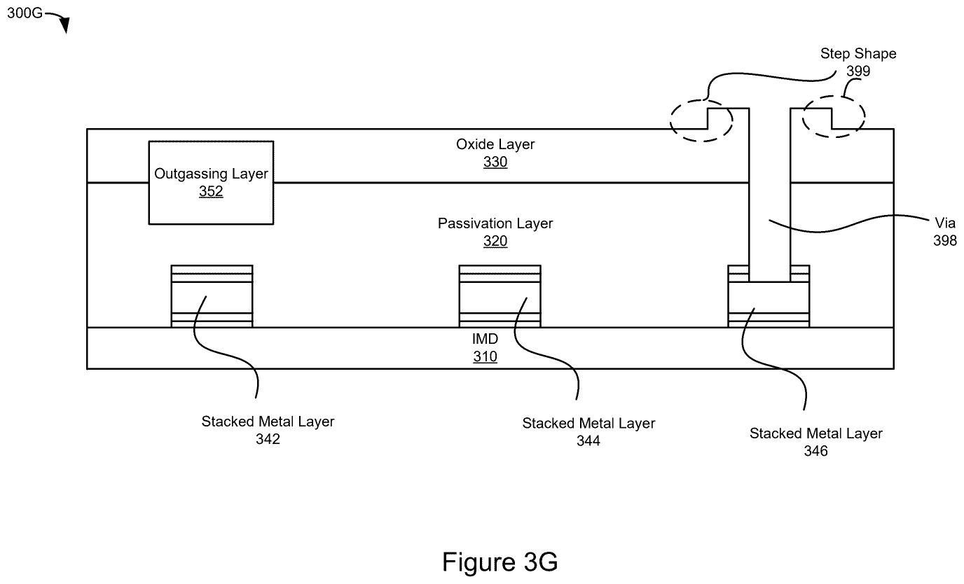

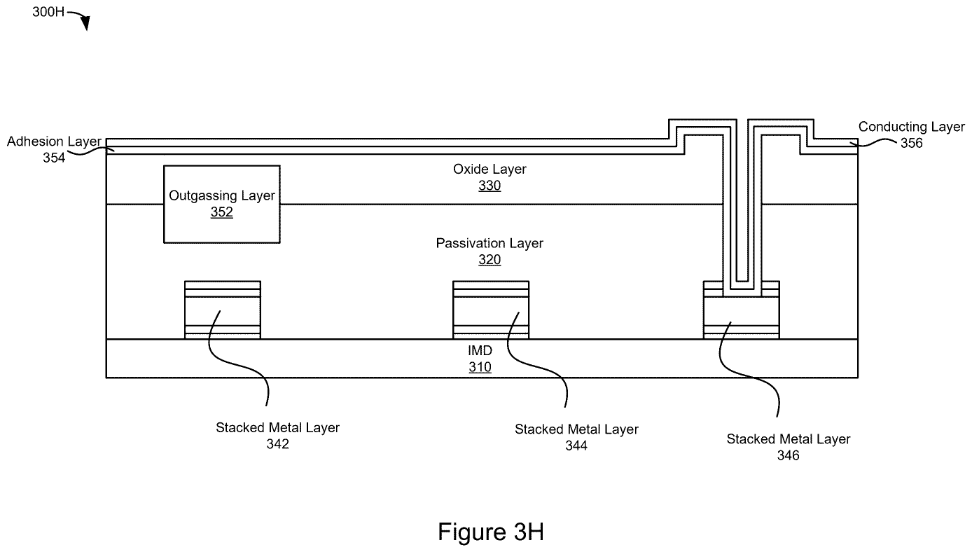

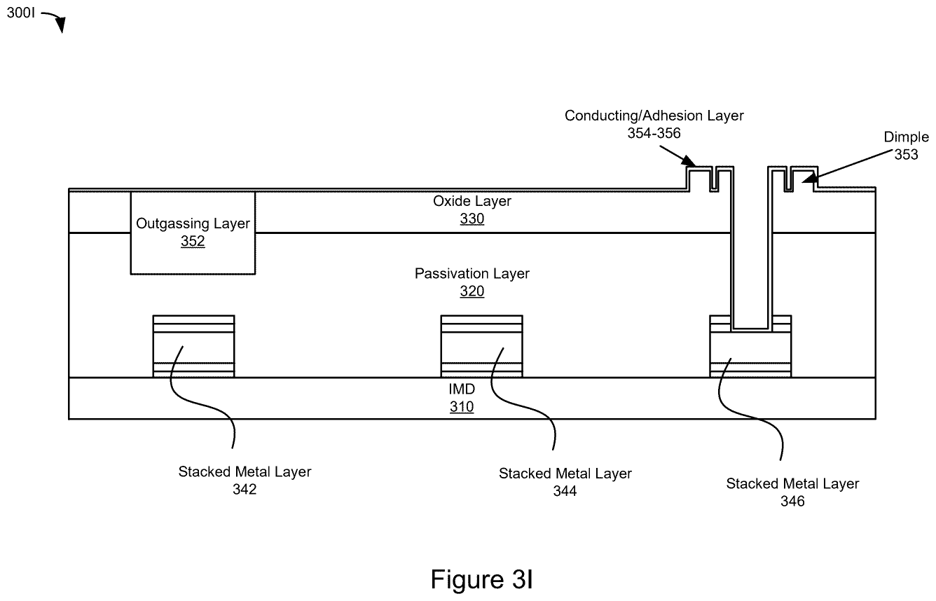

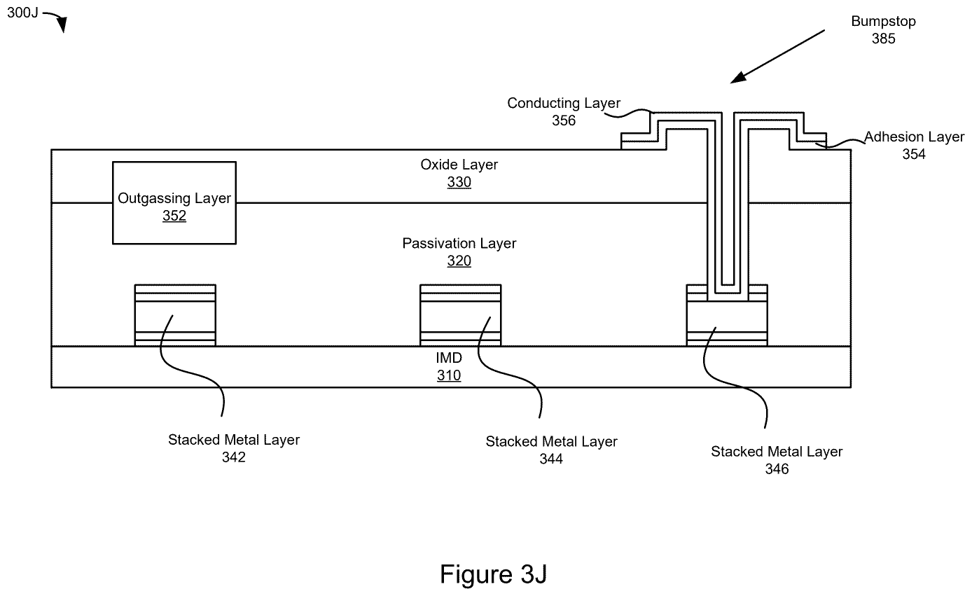

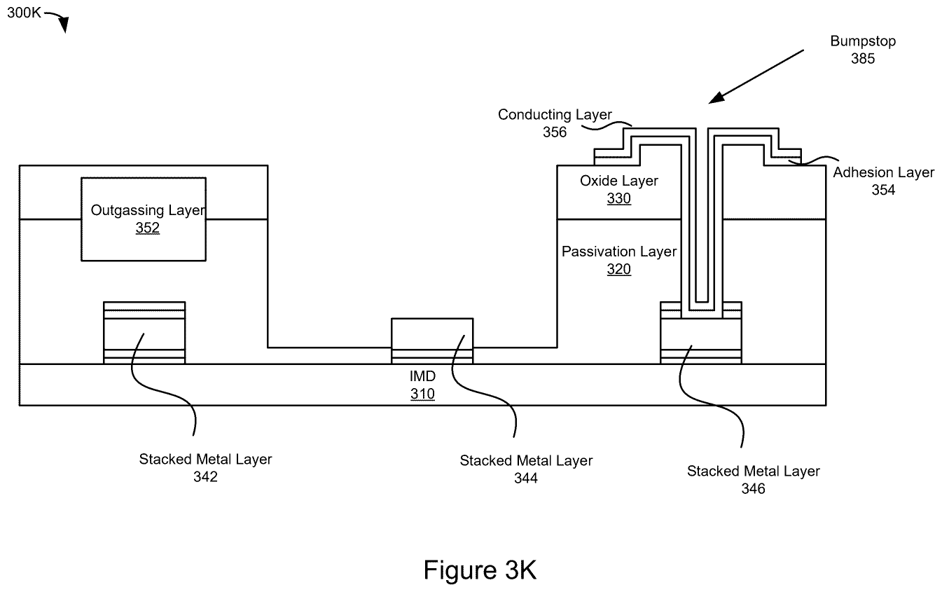

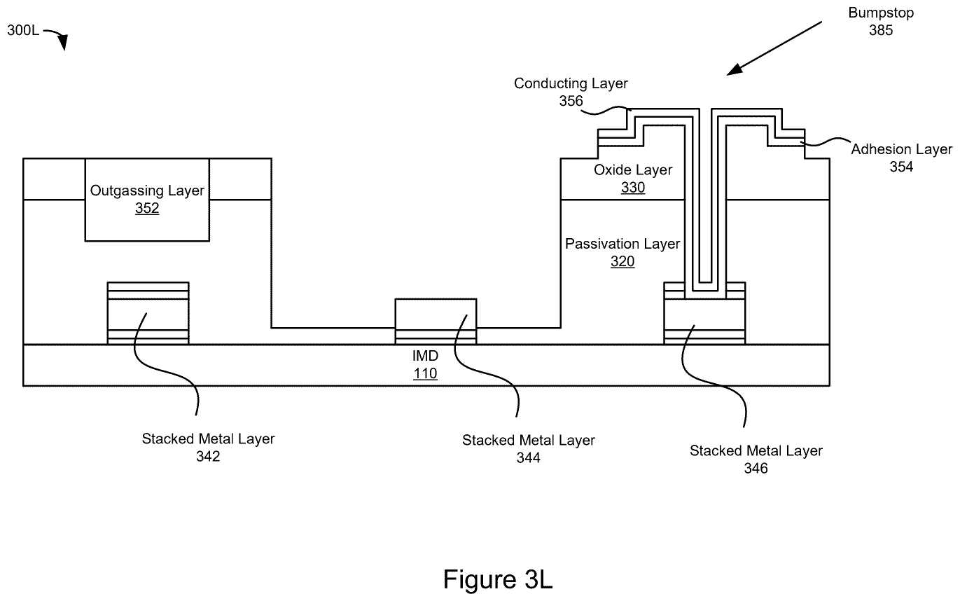

It is appreciated that a number of different processes may be used to create a step shape bumpstop to restrict the actuator from making contact with the adhesion layer. The processes are described in FIGS. 3A-3L, FIGS. 4A-4H, FIGS. 5A-5J, and FIGS. 6A-6G, as described below. The bumpstop may be formed on a substrate, e.g., a silicon wafer, a CMOS, etc.

FIGS. 3A-3L show a process of forming a bumpstop according to one aspect of the present embodiments. FIG. 3A, shows a device 300A with intermetal dielectric (IMD) 310 layer, e.g., SiO₂, SiN, etc. A passivation layer 320, e.g., SiN, may be formed over the IMD 310 layer. A plurality of stacked metal layers may be formed within the passivation layer 320. For example, a stacked metal layers 342, 344, and 346 may be formed within the passivation layer 320. The stacked metal layers may include a number of metal layers stacked on top of one another. For example, the stacked metal layer 342 may include five layers with the adhesion layer in direct contact with the IMD 310 layer and a conductive layer is the top layer of the stack of metal layers. The five layer structure of the stacked metal layer is shown for illustrative purposes only and should not be construed as limiting the scope of the embodiments. For example, a three layer structure or a two layer structure may be used. An oxide layer 330 may be formed over the passivation layer 320. In the described embodiments, adhesion layer 212/212a comprises Titanium (Ti), and conductive layer 214/214a comprises Titanium Nitride (TiN).

Referring now to FIG. 3B, device 300B is shown. It is appreciated that device 300B and process illustrates a process to deposit outgassing layer that may be used in sensors to control the cavity pressure, e.g., accelerometer, as opposed to where the pressure does not need to be controlled, e.g., gyro. In this example, a mask may be pattern to leave a portion of the device 300B exposed that is associated with the outgassing layer area. The device 300B may go through a passivation etch process that removes a portion of the oxide layer 330 as well as a portion of the passivation layer 320 that is exposed (not covered by the mask). In this example, the outgassing layer is being formed over the stacked metal layer 342.

Referring now to FIG. 3C, a device 300C is shown where the cavity formed within the oxide layer 330 and the passivation layer 320 is filled with outgassing layer 352 (substance). The outgassing layer 352 comprises High Density Plasma—chemical vapor deposition(HDP-CVD) oxide composed of silicon based dielectrics such as silicon oxide and silicon nitride may be used for releasing gases in the in accelerometer cavity there by increasing the pressure.

Referring now to FIG. 3D, a device 300D is shown. In FIG. 3D, a mask 372 (a recess mask) may be formed to protect a region on the oxide layer 330 that corresponds to where the bumpstop will be formed at a later stage. The bumpstop will be formed corresponding to the stacked metal layer 346. Once the mask 372 is formed, the surface of device 300C may be etched where exposed (not covered by the mask 372), thereby removing a layer from the oxide layer 330 and the outgassing layer 352. As such, a step is formed.

Referring now to FIG. 3E, device 300E is shown. In this example, the region corresponding to the bumpstop is formed with dimple 353 that further reduces stiction. In this example, the mask 374 may be formed and patterned. As such, during the etching process of device 300C, the exposed portions of the oxide layer 330 within the region that corresponds to the bumpstop (area of stacked metal layer 346) is also etched that forms the dimple 353.

The process as illustrated in FIGS. 3F-H, and FIGS. 3J-3L is performed regardless of whether the dimple 353 is formed. For illustrative purposes, the process is described for the device 300D without dimple 353. Referring now to FIG. 3F, a layer of oxide is added to the oxide 330, thereby thickening the previous layer of oxide and also covering the outgassing layer 352 with a layer of oxide, to form a device 300F.

Referring now to FIG. 3G, a device 300G is shown. In this example, a mask is formed over the device 300F that is pattern to expose a region above the stacked metal layer 346. Once the mask is patterned, the device is etched to form a via 398 within the oxide layer 330 and the passivation layer 320 to expose a layer within the stacked metal layer 346. In this example, the AlCu layer is exposed by the etching for illustrative purposes and should not be construed as limiting the scope of the embodiments. For example, the etching process may expose the top layer TiN without exposing the AlCu layer. It is appreciated that the step 399 is formed.

Referring now to FIG. 3H, device 300H is shown. A metal adhesion layer 354, e.g., Ti, Tantalum (Ta), chromium, etc., is deposited over the oxide layer 330 as well as in the via 398 and over the step 399. In one nonlimiting example, the metal adhesion layer 354 is deposited over the expose metal layer of the stacked metal layer 346. A conducting layer 356, e.g., Titanium Nitride (TiN), Titanium Tungsten (TiW), Tantalum Nitride (TaN), etc., is deposited over the adhesion layer 354. It is appreciated that the metal adhesion layer 354 and the conducting layer 356 cover the vertical side wall of the step 399. In one nonlimiting example, the metal adhesion layer 354 and the conducting layer 356 cover a lower horizontal layer of the step 399.

Referring now to FIG. 3I, a device 300I is shown. In this nonlimiting example, the dimple 353 was formed, as described in FIG. 3E. Subsequently, the via 398 was formed and the adhesion layer 354 and the conducting layer 356 are formed over the oxide layer 330 in addition to the dimple 353 and the via 398.

Referring now to FIG. 3J, a device 300J is shown following the process from FIG. 3H. In this nonlimiting example, a mask (e.g., TiN mask) is used and patterned to cover a portion of the metal conducting layer 356 and the metal adhesion layer 354 associated with the bumpstop 385 and surrounding area (e.g., region associated with stacked metal layer 346, the via 398, the step 399, and adjacent region) and leaving other areas exposed. The exposed conducting layer 356 is etched (e.g., dry etch) and subsequent to that the exposed adhesion layer 354 is etched. As such, the oxide layer 330 is exposed whereas the region associated with the bumpstop 385 associated with the stacked metal layer 346, the via 398, and adjacent region maintain the conducting metal layer 356 and the adhesion layer 354. In other words, the metal adhesion layer 354 and the conducting metal layer 356 are patterned to maintain the conducting metal layer 356 and the metal adhesion layer 354 within the via 398, and the step shape 399 formed in the oxide layer 330, to form the bumpstop 385. In one nonlimiting example, the patterning is done to retain the metal adhesion layer 354 and conducting metal layer 356 over the vertical side wall of the step shape 399.

Referring now to FIG. 3K, a device 300K is shown. In this nonlimiting example, a mask is used to protect the area associated with the outgassing layer 352 in addition to protecting the region associated with bumpstop 385 (e.g., stacked metal layer 346, the via 398, and adjacent region that includes the conducting layer 356 and the adhesion layer 354, etc.) while exposing an oxide region associated with the stacked metal layer 344. A passivation etch may be performed to etch the oxide layer 330 and the passivation layer 320 above the stacked metal layer 344 in addition to the adjacent regions around the stacked metal layer 344, thereby exposing the layer of the stacked metal layer 344. In this nonlimiting example, the top two layers of the stacked metal layer 344 are also etched away to expose the AlCu layer. However, etching the top two layers of the stacked metal layer 344 is for illustrative purposes and should not be construed as limiting the scope of the embodiments. For example, the etch process may leave the top two layers of the stacked metal layer 344 in place.

Referring now to FIG. 3L, a device 300L is shown. In this nonlimiting example, a layer of the oxide layer 330 is etched away to expose the outgassing layer 352. It is appreciated that a portion of the oxide layer 330 associated with the bumpstop 385 may also be etched away during this process. In other words, etching the exposed oxide layer 330 associated with the bumpstop 385 may form a second step shape. As illustrated, a second step in the oxide layer 330 in the outer periphery of the bumpstop 385. The device 300L is a substrate wafer that is ready for eutectic bonding with a MEMS wafer (e.g., device layer of the MEMS wafer).

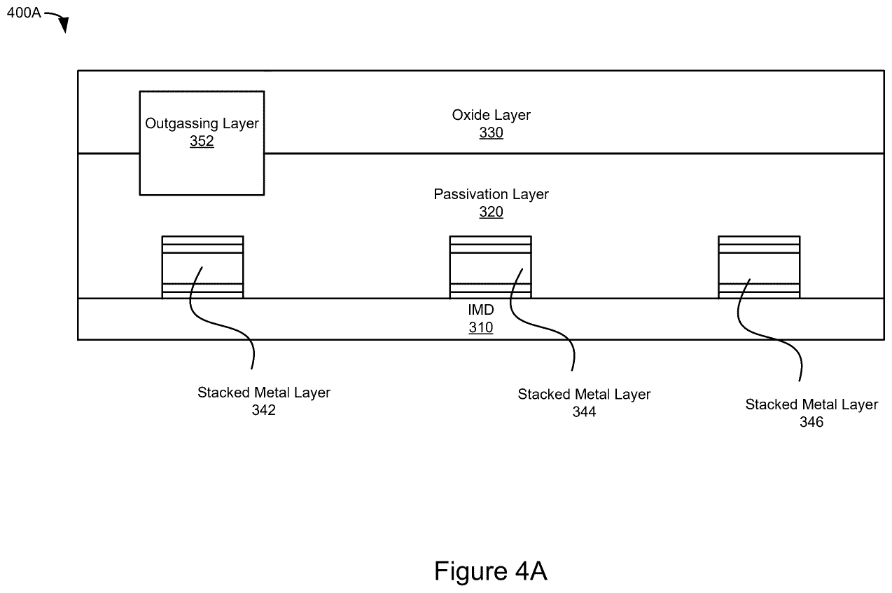

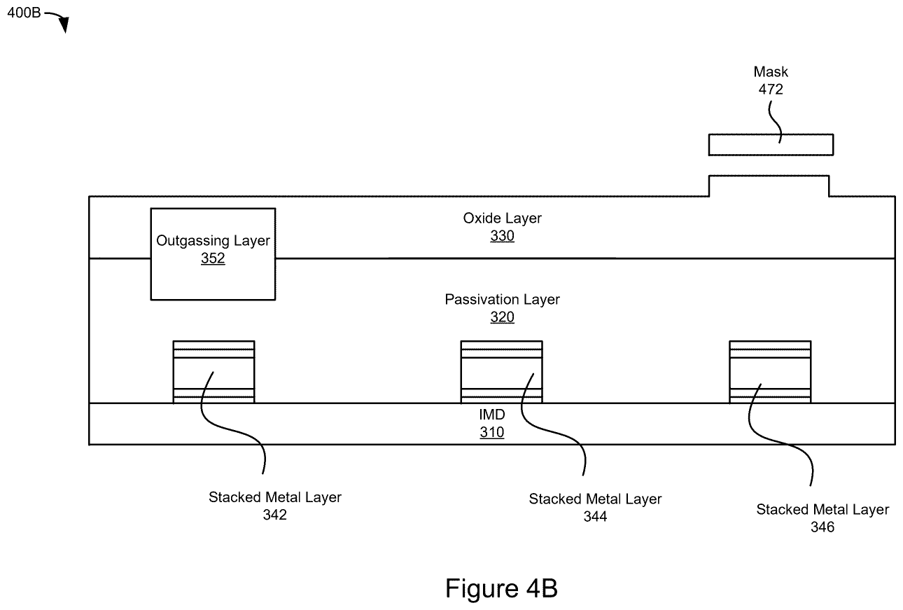

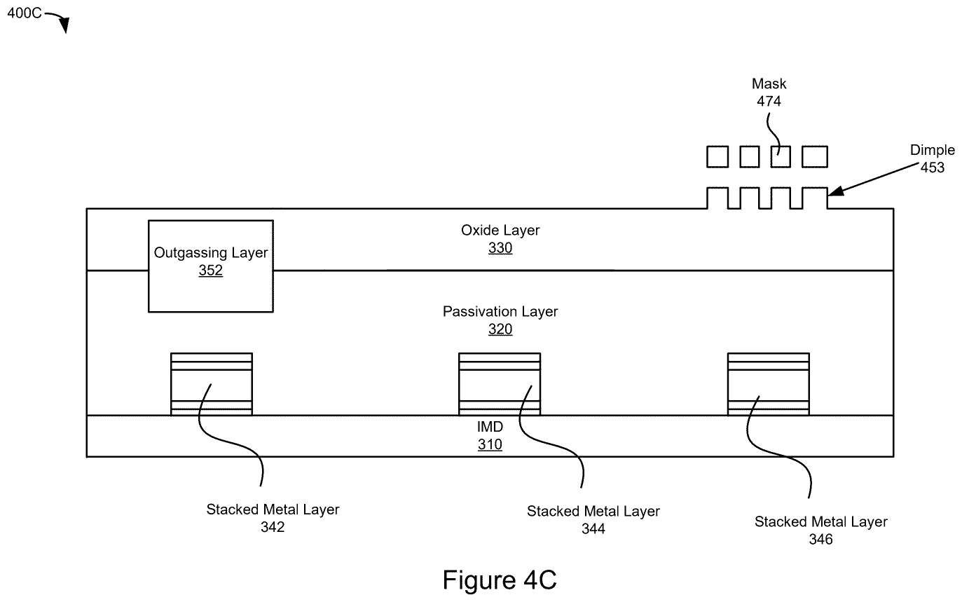

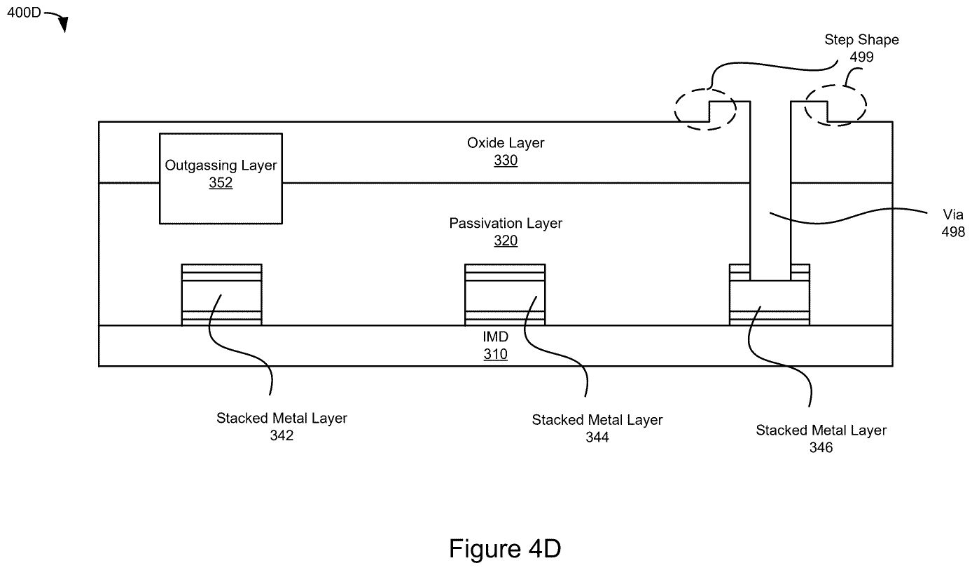

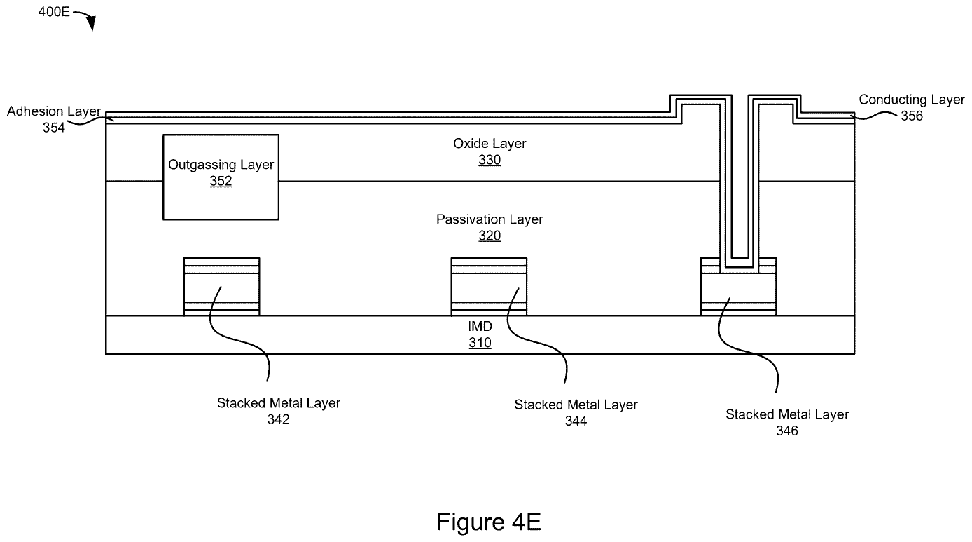

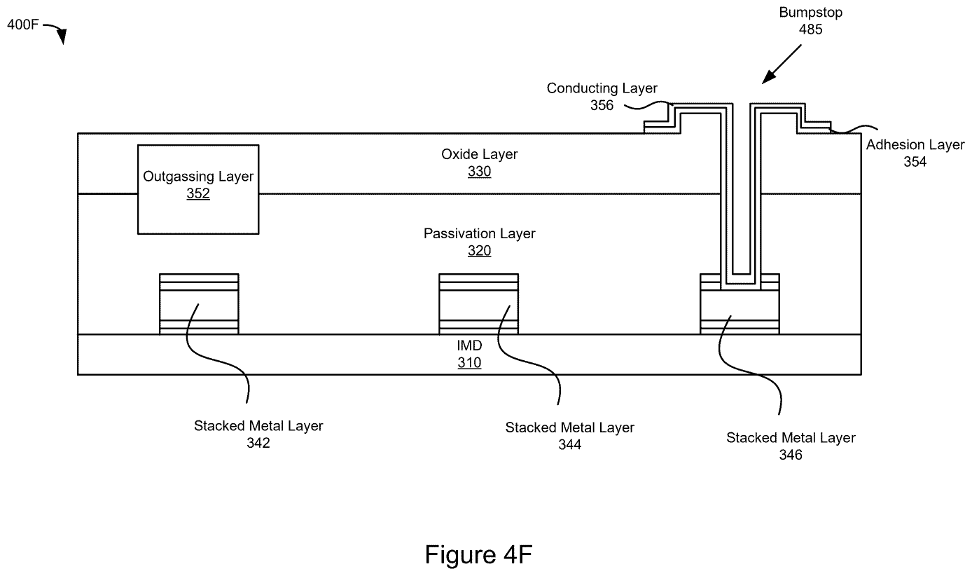

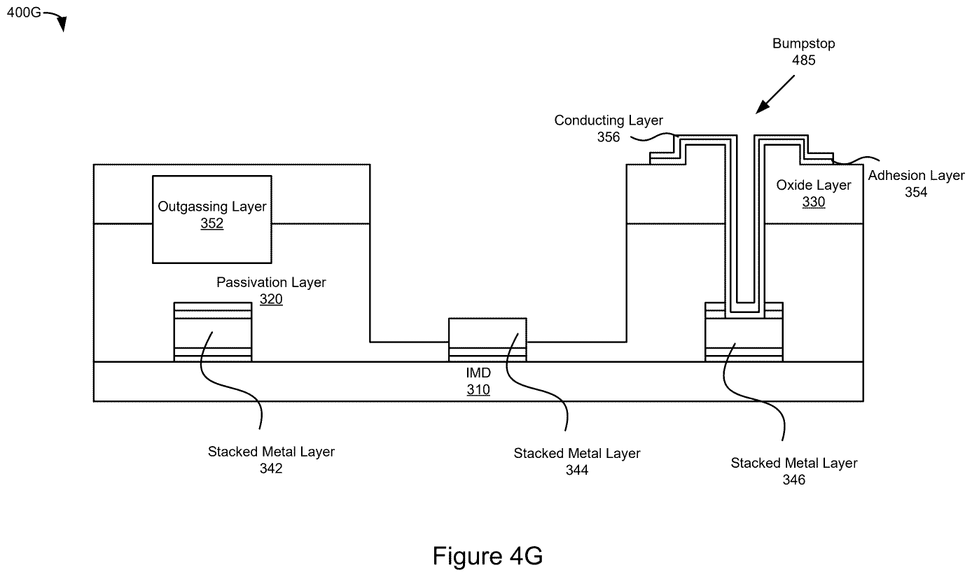

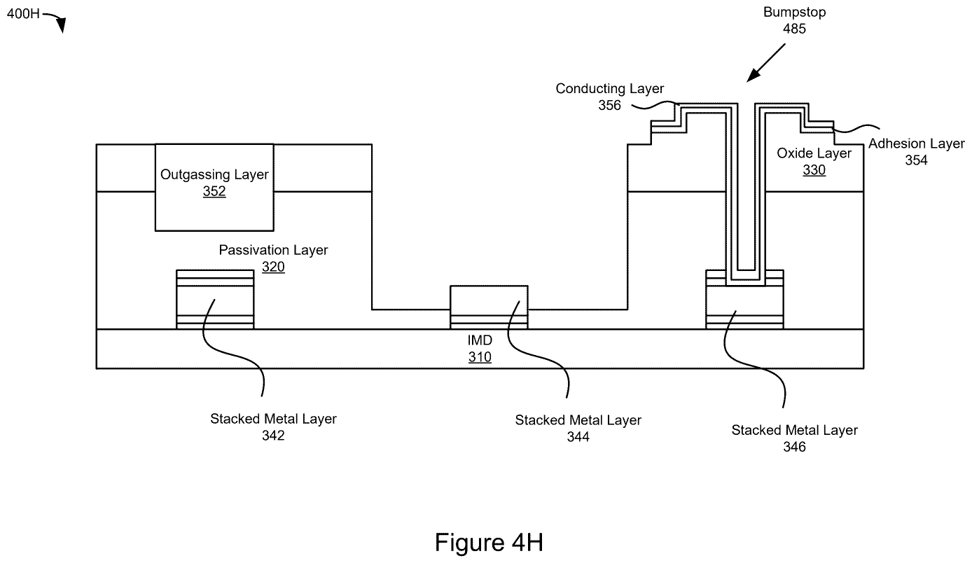

FIGS. 4A-4H show another process of forming another bumpstop according to one aspect of the present embodiments. Referring now to FIG. 4A, a device 400A is shown where a layer of oxide is deposited over the outgassing layer 352 and the oxide layer 330 of device 300C in FIG. 3C. As such, the thickness of the oxide layer 330 is increased and the outgassing layer 352 is no longer exposed. Referring now to FIG. 4B, a device 400B is shown where a mask 472 is formed over a region of the oxide layer 330 associated with the bumpstop to be formed (e.g., above the stacked metal layer 346). Once the mask 472 is formed, the etching process begins to etch away the exposed portion of the oxide layer 330, thereby forming a step associated with the bumpstop (e.g., above the stacked metal layer 346). In one nonlimiting example, the etching process maintains a layer of oxide layer 330 over the outgassing layer 352 to protect it in the subsequent etching process. Referring now to FIG. 4C, a device 400C is shown. In this nonlimiting example, the bumpstop region is formed with a dimple 453 (similar to FIG. 3E). In FIG. 4C, the mask 474 is formed and is patterned to etch away portions of the oxide layer 330 to form the dimple 453.

The process as illustrated in FIGS. 4D-4H is performed regardless of whether the dimple 453 is formed. For illustrative purposes, the process is described for the device 400B without dimple 453. Referring now to FIG. 4D, a device 400D is shown. In this nonlimiting example, a mask is formed and patterned to expose a region of the oxide layer 330 associated with a bumpstop. The exposed region of the oxide layer 330 is etched to form a via 498. The via 498 may extend to expose one or more layers of the stacked metal layer 346. In this nonlimiting example, the via 498 exposes the AlCu layer of the stacked metal layer 346. It is appreciated that the step shape 499 is also formed, as described in FIG. 4B.

Referring now to FIG. 4E, a device 400E is shown where an adhesion layer 354 is deposited over the oxide layer 330 in addition to the via 498 and on the exposed metal layer of the stacked metal layer 346 (similar to FIG. 3H). It is appreciated that the metal adhesion layer 354 and the conducting layer 356 cover the vertical side wall of the step 499. In one nonlimiting example, the metal adhesion layer 354 and the conducting layer 356 cover a lower horizontal layer of the step 499.

Referring now to FIG. 4F a device 400F is shown following the process from FIG. 4E. In this nonlimiting example, a mask (e.g., TiN mask) is used and patterned to cover a portion of the metal conducting layer 356 and the metal adhesion layer 354 associated with the bumpstop 485 and surrounding area (e.g., region associated with stacked metal layer 346, the via 498, the step 499, and adjacent region) and leaving other areas exposed. The exposed conducting layer 356 is etched (e.g., dry etch) and subsequent to that the exposed adhesion layer 354 is etched. As such, the oxide layer 330 is exposed whereas the region associated with the bumpstop 485 associated with the stacked metal layer 346, the via 498, and adjacent region maintain the conducting metal layer 356 and the adhesion layer 354. In other words, the metal adhesion layer 354 and the conducting metal layer 356 are patterned to maintain the conducting metal layer 356 and the metal adhesion layer 354 within the via 498, and the step shape 499 formed in the oxide layer 330, to form the bumpstop 485. In one nonlimiting example, the patterning is done to retain the metal adhesion layer 354 and conducting metal layer 356 over the vertical side wall of the step shape 499.

Referring now to FIG. 4G, a device 400G is shown. In this nonlimiting example, a mask is used to protect the area associated with the outgassing layer 352 in addition to protecting the region associated with bumpstop 485 (e.g., stacked metal layer 346, the via 498, and adjacent region that includes the conducting layer 356 and the adhesion layer 354, etc.) while exposing an oxide region associated with the stacked metal layer 344. A passivation etch may be performed to etch the oxide layer 330 and the passivation layer 320 above the stacked metal layer 344 in addition to the adjacent regions around the stacked metal layer 344, thereby exposing the layer of the stacked metal layer 344. In this nonlimiting example, the top two layers of the stacked metal layer 344 are also etched away to expose the AlCu layer. However, etching the top two layers of the stacked metal layer 344 is for illustrative purposes and should not be construed as limiting the scope of the embodiments. For example, the etch process may leave the top two layers of the stacked metal layer 344 in place.

Referring now to FIG. 4H, a device 400H is shown. In this nonlimiting example, a layer of the oxide layer 330 is etched away to expose the outgassing layer 352. It is appreciated that a portion of the oxide layer 330 associated with the bumpstop 485 may also be etched away during this process. In other words, etching the exposed oxide layer 330 associated with the bumpstop 485 may form a second step shape. The device 400H is a substrate wafer that is ready for eutectic bonding with a MEMS wafer (e.g., device layer of the MEMS wafer).

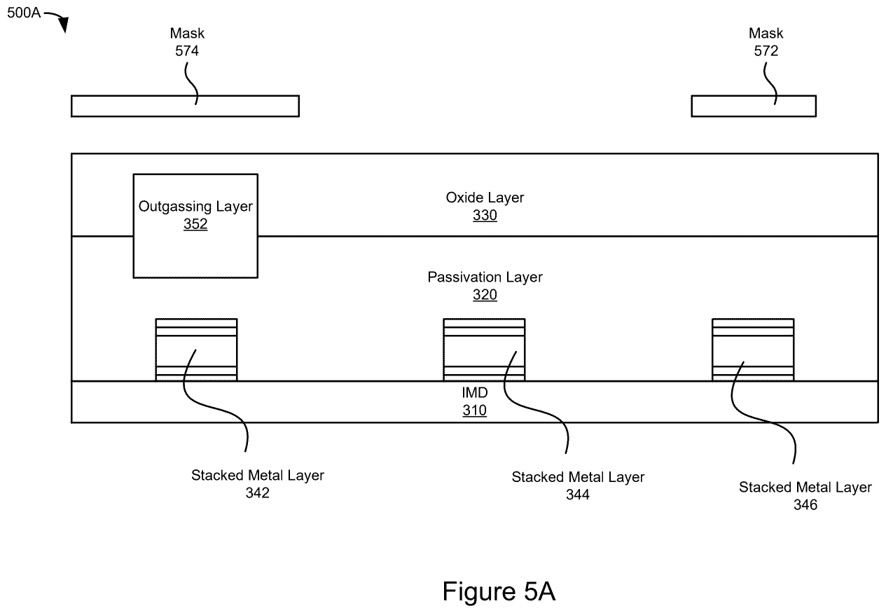

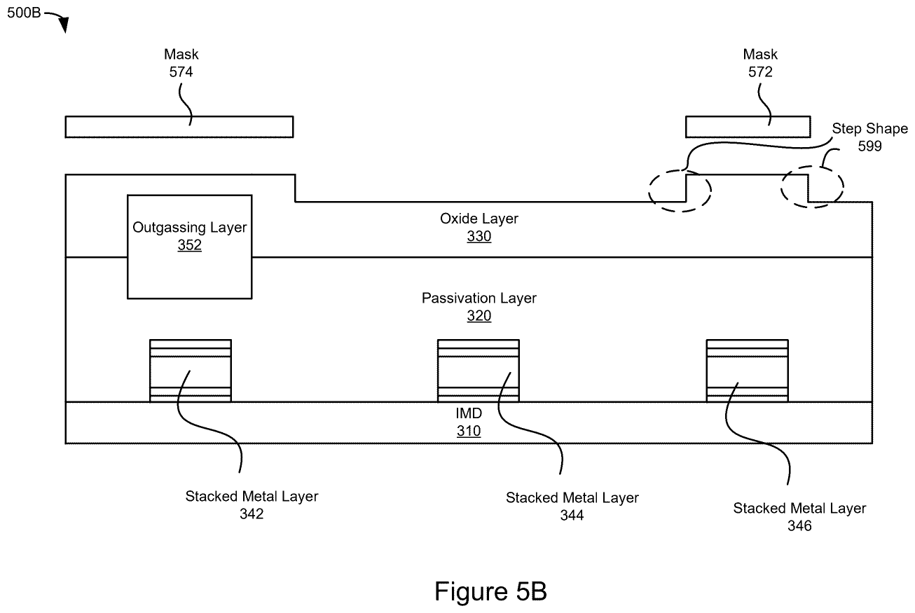

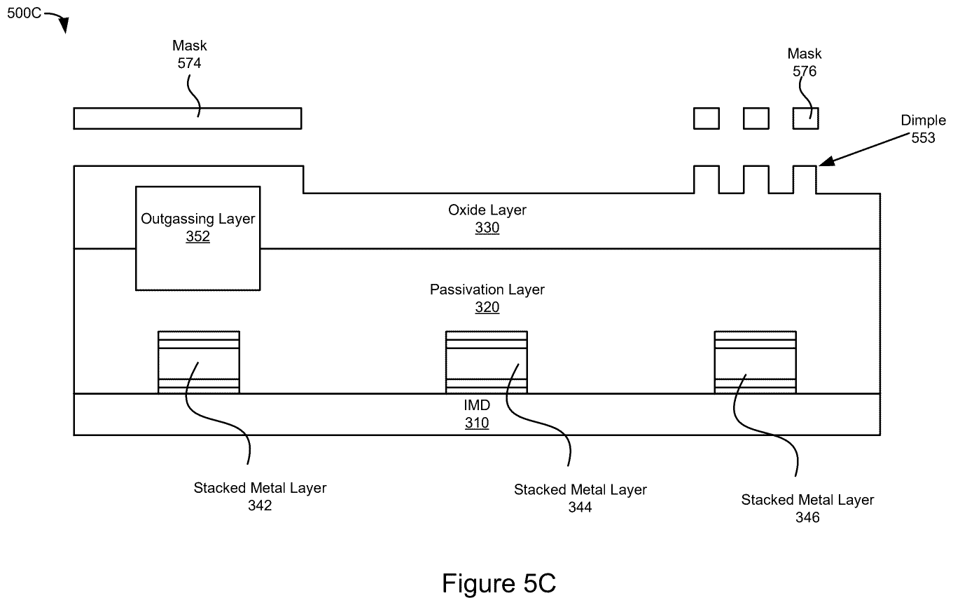

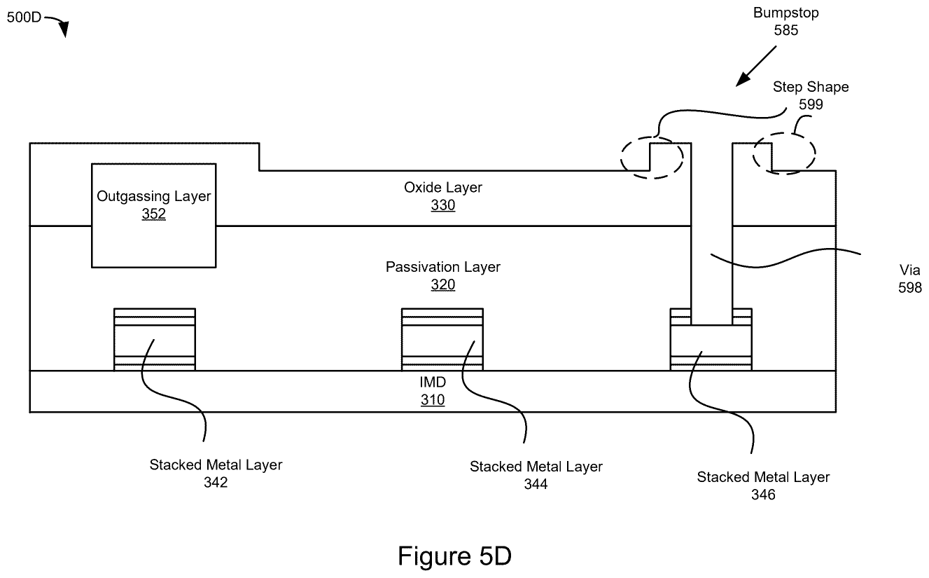

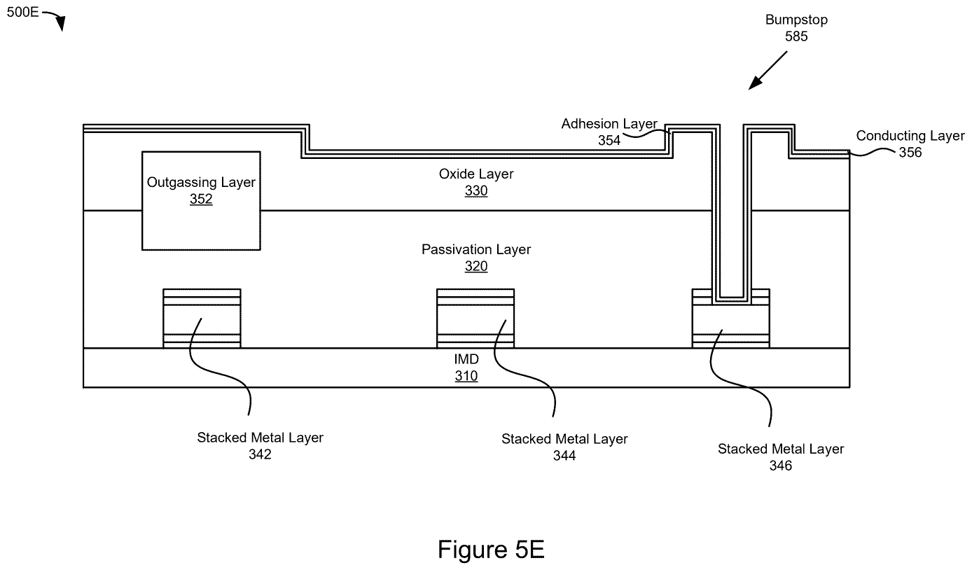

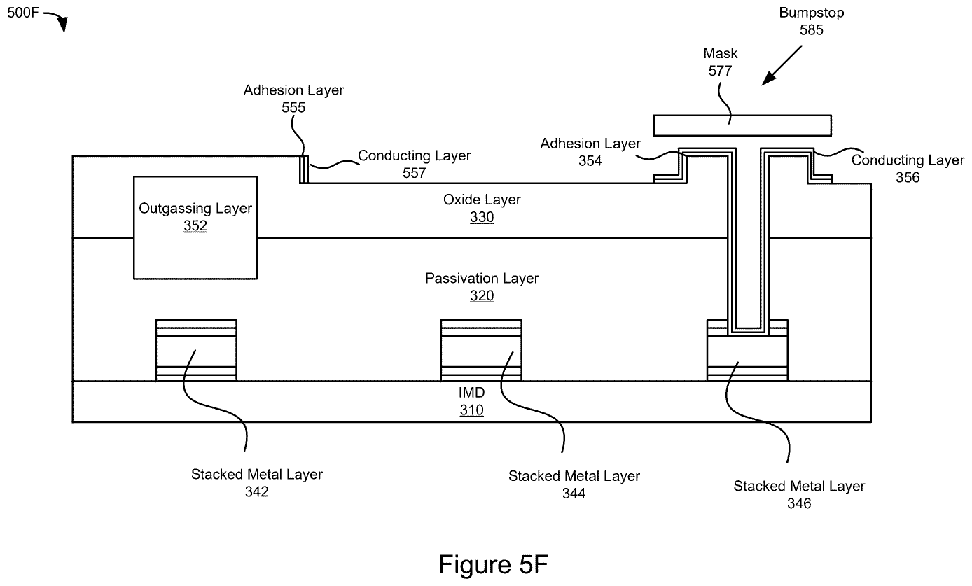

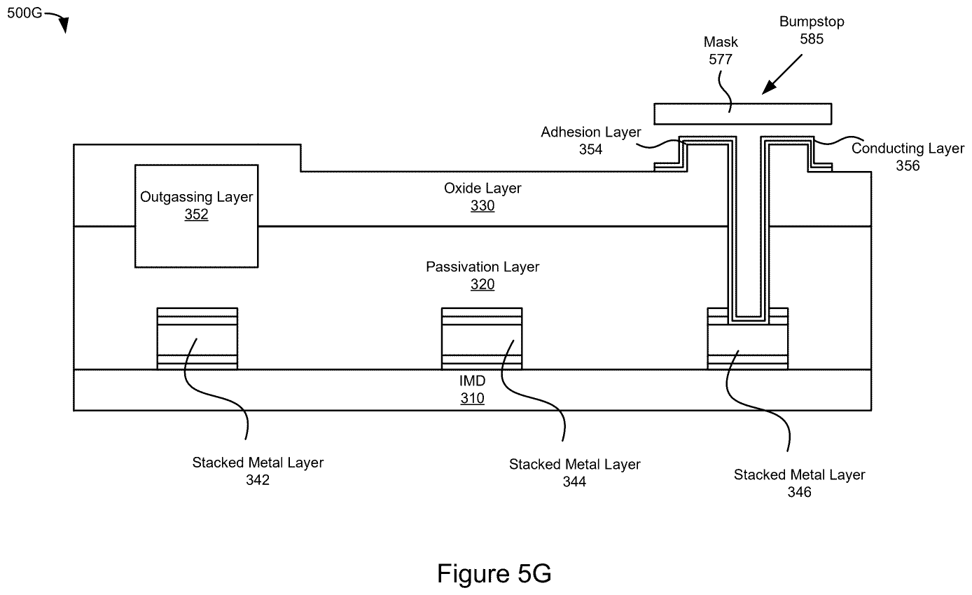

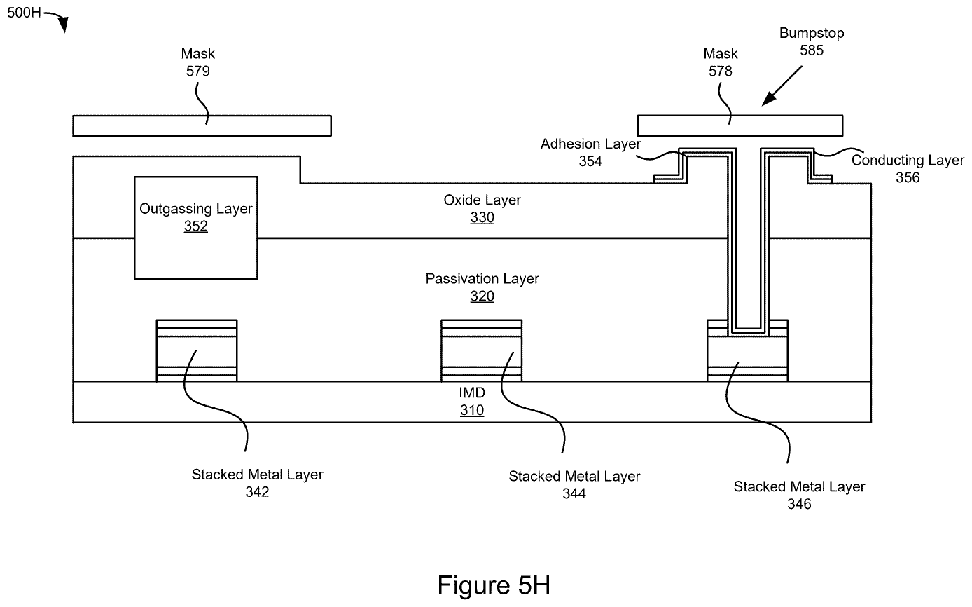

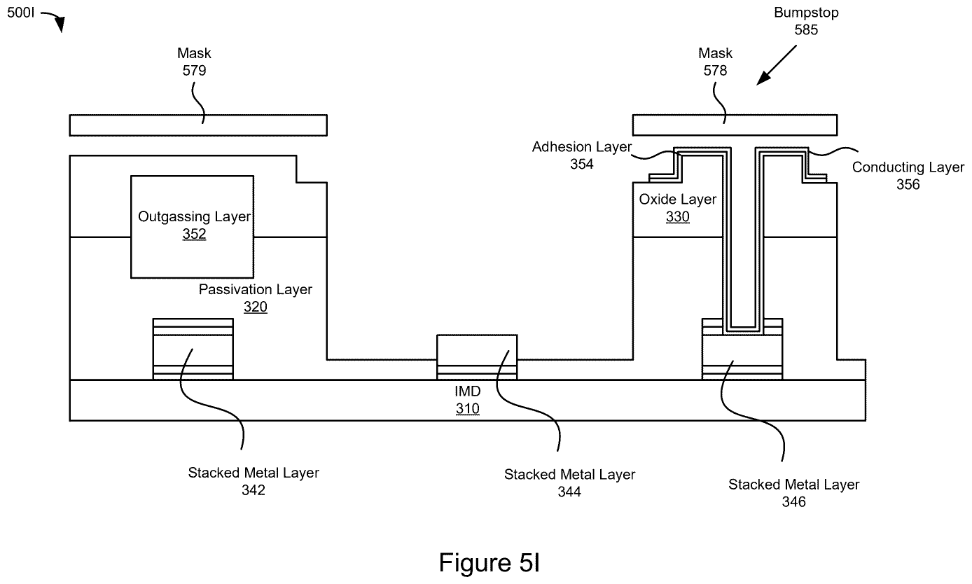

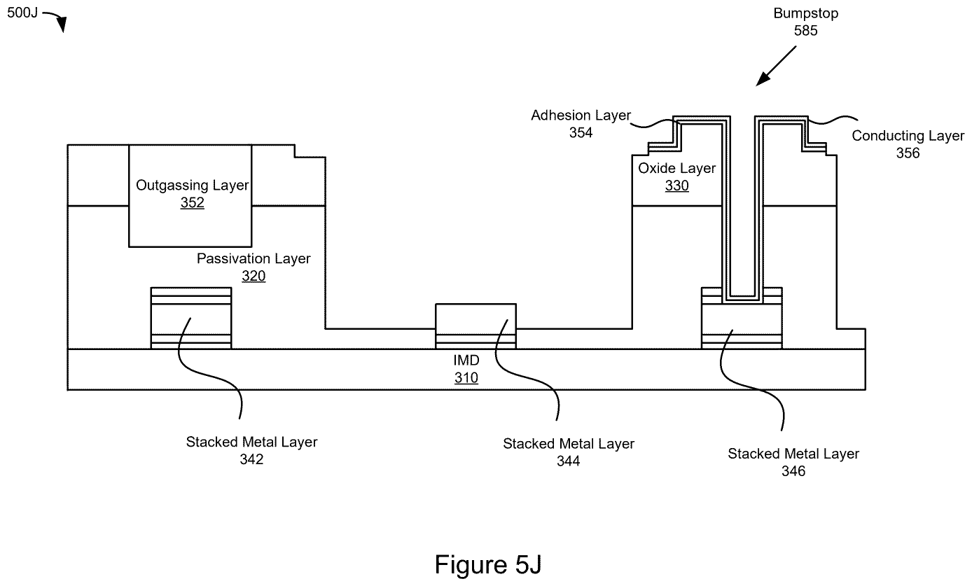

FIGS. 5A-5J show yet another process of forming yet another bumpstop according to one aspect of the present embodiments. Referring now to FIG. 5A, a device 500A is shown that is similar to that of FIG. 4A. In this nonlimiting example, a mask 572 and 574 are formed over the oxide layer 330. The mask 572 may be aligned with the region associated with a bumpstop to be formed and the mask 574 may be aligned with the outgassing region. Referring now to FIG. 5B, a device 500B is shown where the exposed oxide region of the oxide layer 330 is etched away, forming a step shape 599.

Referring now to FIG. 5C, a device 500C is shown. In this nonlimiting example, the bumpstop region is formed with a dimple 553 (similar to FIG. 4C). In FIG. 5C, the mask 576 is formed and is patterned to etch away portions of the oxide layer 330 to form the dimple 553.

The process as illustrated in FIGS. 5D-5J is performed regardless of whether the dimple 553 is formed. The masks of FIG. 5B or 5C are removed. For illustrative purposes, the process is described for the device 500B without dimple 553. Referring now to FIG. 5D, a device 500D is shown. In this nonlimiting example, a mask is formed and patterned to expose a region of the oxide layer 330 associated with a bumpstop 585. The exposed region of the oxide layer 330 is etched to form a via 598. The via 598 may extend to expose one or more layers of the stacked metal layer 346. In this nonlimiting example, the via 598 exposes the AlCu layer of the stacked metal layer 346. It is appreciated that the step shape 599 is also formed, as described in FIG. 5B.

Referring now to FIG. 5E, a device 500E is shown where an adhesion layer 354 is deposited over the oxide layer 330 in addition to the via 598 and on the exposed metal layer of the stacked metal layer 346 (similar to FIG. 4E). It is appreciated that the metal adhesion layer 354 and the conducting layer 356 cover the vertical side wall of the step 599. In one nonlimiting example, the metal adhesion layer 354 and the conducting layer 356 cover a lower horizontal layer of the step 599.

Referring now to FIG. 5F a device 500F is shown following the process from FIG. 5E. In this nonlimiting example, a mask 577 (e.g., TiN mask) is used and patterned to cover a portion of the metal conducting layer 356 and the metal adhesion layer 354 associated with the bumpstop 585 and surrounding area (e.g., region associated with stacked metal layer 346, the via 598, the step 599, and adjacent region) and leaving other areas exposed. The exposed conducting layer 356 is etched (e.g., dry etch) and subsequent to that the exposed adhesion layer 354 is etched. As such, the oxide layer 330 is exposed whereas the region associated with the bumpstop 585 associated with the stacked metal layer 346, the via 598, and adjacent region maintain the conducting metal layer 356 and the adhesion layer 354. In other words, the metal adhesion layer 354 and the conducting metal layer 356 are patterned to maintain the conducting metal layer 356 and the metal adhesion layer 354 within the via 598, and the step shape 599 formed in the oxide layer 330, to form the bumpstop 585. In one nonlimiting example, the patterning is done to retain the metal adhesion layer 354 and conducting layer 356 over the vertical side wall of the step shape 599. It is appreciated that during the etching process, the vertical portions of the adhesion layer 555 and conducting layer 557 are not etched away. As such, referring now to FIG. 5G a device 500G is shown where the conducting layer 557 and the adhesion layer 555 are etched away through a wet etch process or isotropic etch.

Referring now to FIG. 5H, a device 500H is shown. In this nonlimiting example, masks 578 and 579 are used to protect the area associated with the outgassing layer 352 in addition to protecting the region associated with bumpstop 585 (e.g., stacked metal layer 346, the via 598, and adjacent region that includes the conducting layer 356 and the adhesion layer 354, etc.) while exposing an oxide region associated with the stacked metal layer 344. Referring now to FIG. 5I, a device 500I is shown. In FIG. 5I, a passivation etch may be performed to etch the oxide layer 330 and the passivation layer 320 above the stacked metal layer 344 in addition to the adjacent regions around the stacked metal layer 344, thereby exposing the layer of the stacked metal layer 344. In this nonlimiting example, the top two layers of the stacked metal layer 344 are also etched away to expose the AlCu layer. However, etching the top two layers of the stacked metal layer 344 is for illustrative purposes and should not be construed as limiting the scope of the embodiments. For example, the etch process may leave the top two layers of the stacked metal layer 344 in place.

The masks 578-579 are removed. Referring now to FIG. 5J, a device 500J is shown. In this nonlimiting example, a layer of the oxide layer 330 is etched away to expose the outgassing layer 352. It is appreciated that a portion of the oxide layer 330 associated with the bumpstop 585 may also be etched away during this process. In other words, etching the exposed oxide layer 330 associated with the bumpstop 585 may form a second step shape. The device 500J is a substrate wafer that is ready for eutectic bonding with a MEMS wafer (e.g., device layer of the MEMS wafer).

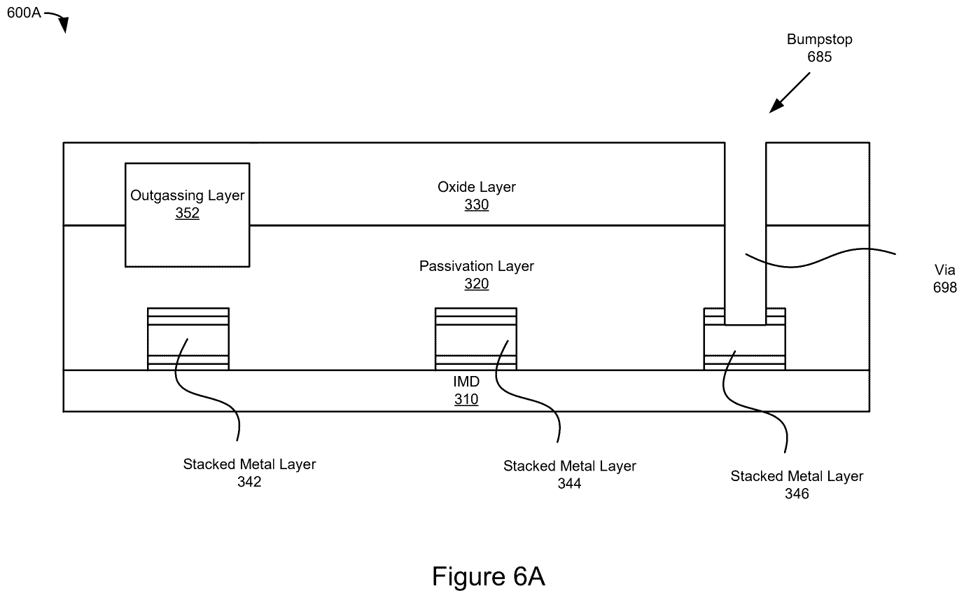

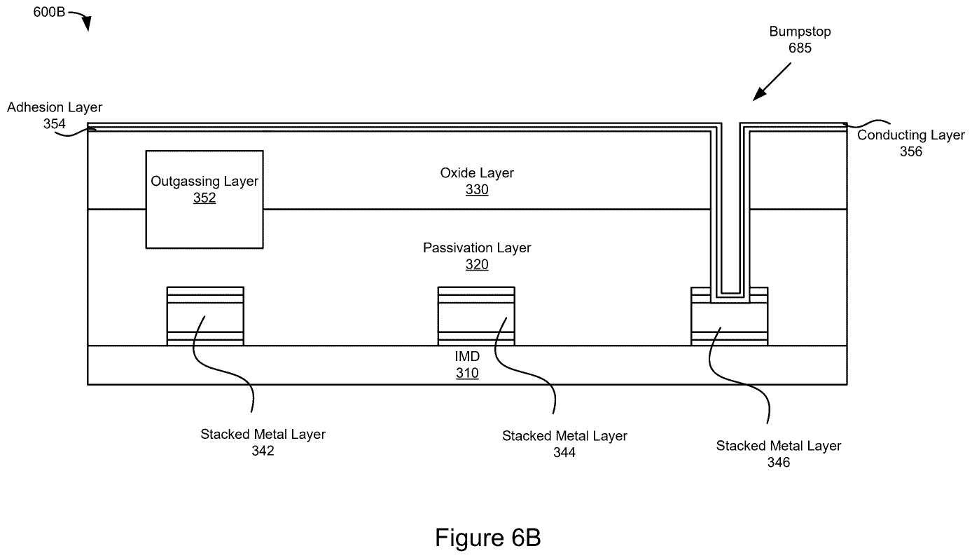

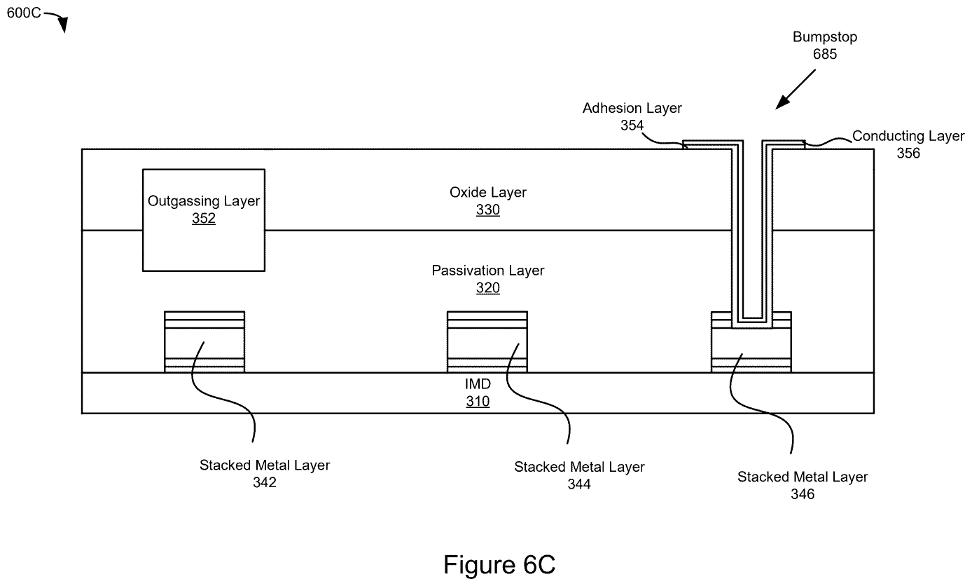

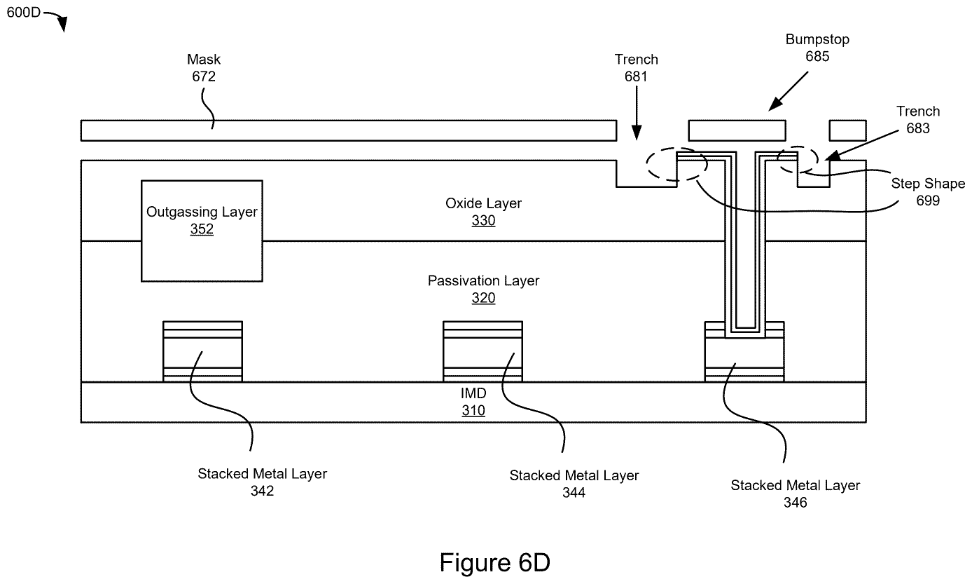

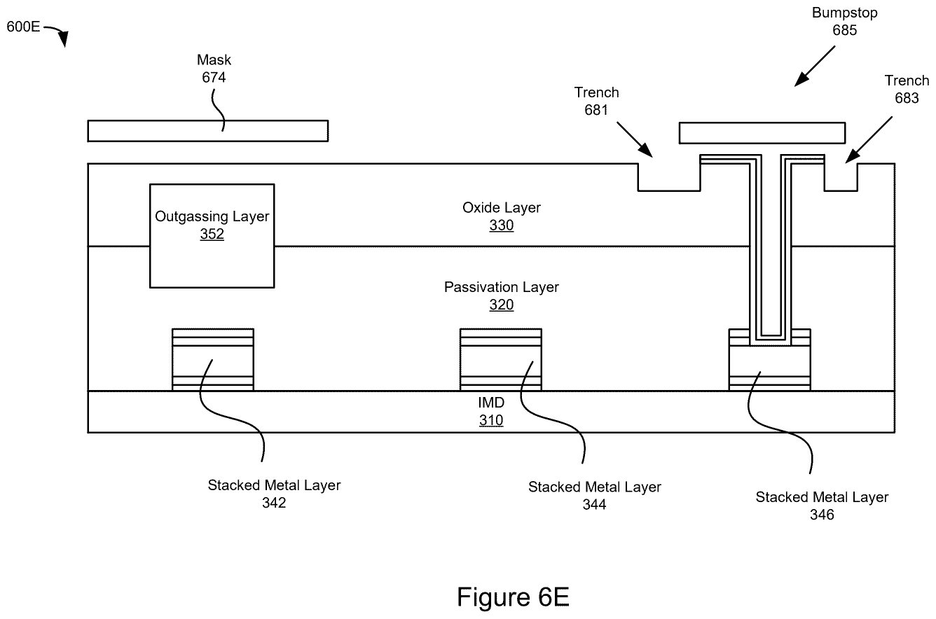

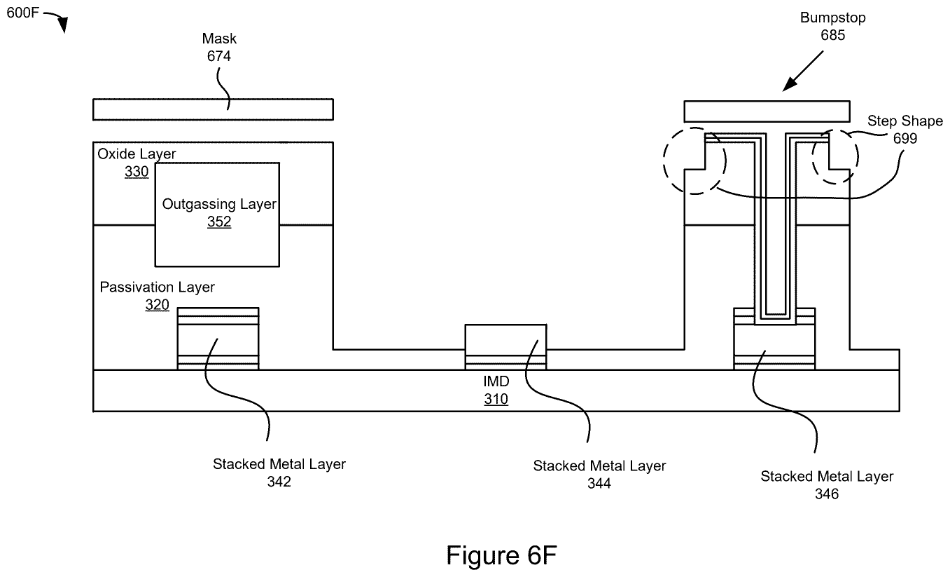

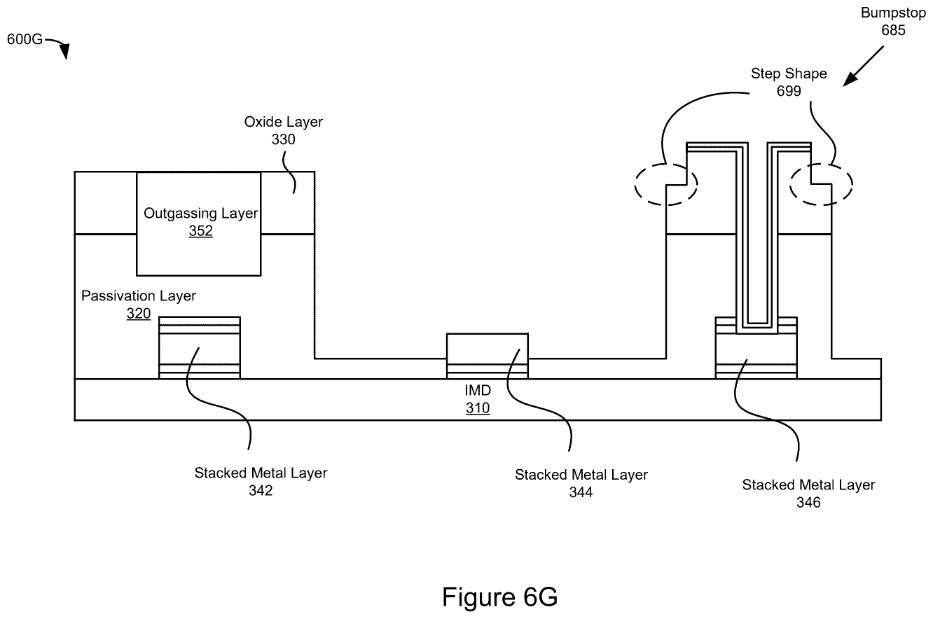

FIGS. 6A-6G show even another process of forming a bumpstop according to one aspect of the present embodiments. FIG. 6A shows a device 600A that is similar to device 400A of FIG. 4A. In FIG. 6A, a mask is formed and patterned to expose a region of the oxide layer 330 associated with a bumpstop. The exposed region of the oxide layer 330 is etched to form a via 698 associated with a bumpstop 685. The via 698 may extend to expose one or more layers of the stacked metal layer 346. In this nonlimiting example, the via 698 exposes the AlCu layer of the stacked metal layer 346.

Referring now to FIG. 6B, a device 600B is shown where an adhesion layer 354 is deposited over the oxide layer 330 in addition to the via 698 and on the exposed metal layer of the stacked metal layer 346 (similar to FIG. 4E).

Referring now to FIG. 6C a device 600C is shown following the process from FIG. 5C. In this nonlimiting example, a mask (e.g., TiN mask) is used and patterned to cover a portion of the metal conducting layer 356 and the metal adhesion layer 354 associated with the bumpstop 685 and surrounding area (e.g., region associated with stacked metal layer 346, the via 698, and adjacent region) and leaving other areas exposed. The exposed conducting layer 356 is etched (e.g., dry etch) and subsequent to that the exposed adhesion layer 354 is etched. As such, the oxide layer 330 is exposed whereas the region associated with the bumpstop 685 associated with the stacked metal layer 346, the via 698, and adjacent region maintain the conducting metal layer 356 and the adhesion layer 354. In other words, the metal adhesion layer 354 and the conducting metal layer 356 are patterned to maintain the conducting metal layer 356 and the metal adhesion layer 354 within the via 698 to form the bumpstop 585.

Referring now to FIG. 6D, a device 600D is shown. A mask 672 (a recess mask) may be formed over all regions except for regions where a step shape is to be formed, thereby leaving a portion of the oxide layer 330 exposed. The etching process etches away a portion of the oxide layer 330 that is exposed to create a step shape 699 region associated with the bumpstop 685 and forms trenches 681 and 683.

Referring now to FIG. 6E, a device 600E is shown. In this nonlimiting example, a mask 674 (e.g., a recess mask) is formed to cover the bumpstop 685 region as well as the outgassing region. The mask 674 covers a portion of the step shape 699 while leaving a portion of the trenches 681 and 683 formed within the oxide layer 330 exposed. The mask 674 also leaves an oxide layer 330 region associated with the stacked metal layer 344 exposed.

Referring now to FIG. 6F, a device 600F is shown. The exposed regions (not covered by the mask 674) are etched away. The etching process removes the oxide layer 330 above the stacked metal layer 344 as well as removing the passivation layer 320 to expose a layer of the stacked metal layer 344. In this nonlimiting example, the AlCu layer is exposed. It is appreciated that the exposed region (not covered by the mask 674) to the right of the bumpstop 685 is similarly etched. As such, a step shape 699 is formed.

Referring now to FIG. 6G, a device 600G is shown. In this nonlimiting example, the mask 674 is removed and another etching is performed to expose the outgassing layer 352. It is appreciated that the etching process may etch away a portion of the oxide layer 330 associated with the bumpstop 685 region. It is appreciated that the metal adhesion layer 354 and the conducting layer 356 does not cover the vertical side wall of the step 699. In one nonlimiting example, the metal adhesion layer 354 and the conducting layer 356 does not cover a lower horizontal layer of the step 699.

It is appreciated that in any of the embodiments above where a dimple is formed, the adhesion layer and the conducting layer trace the contours of the dimple.

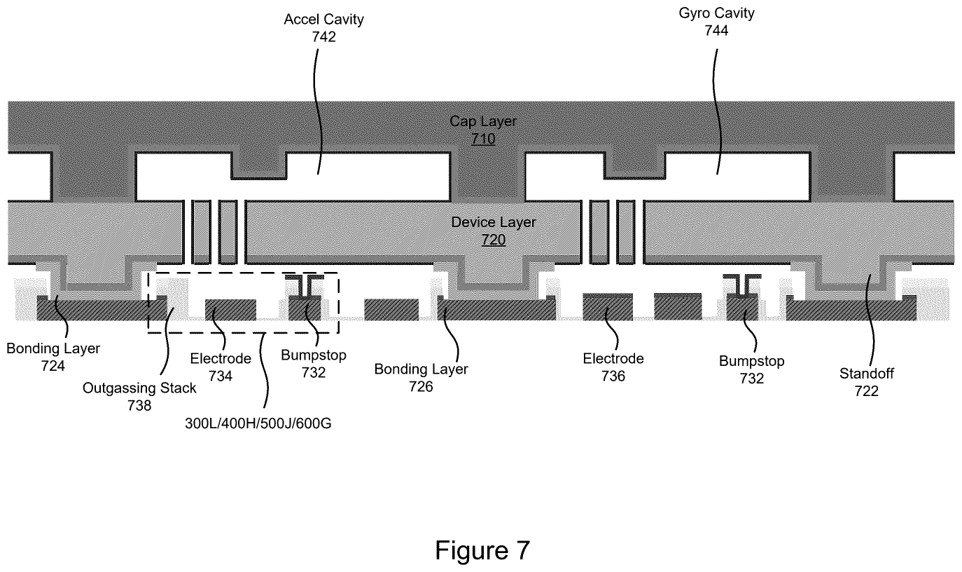

FIG. 7 shows a sensing device with a bumpstop with reduced stiction according to one aspect of the present embodiments. In one nonlimiting example, a MEMS may include a cap layer 710 coupled to a device layer 720 and forms an accel cavity 742 and a gyro cavity 744 for housing moveable structures of gyro, accelerometer, etc. It is appreciated that two cavities are shown for illustrative purposes and should not be construed as limiting the scope of the embodiments. For example, a single cavity may be formed.

It is appreciated that the device layer 720 may have one or more standoffs 722 coated with a bonding layer 724 for coupling to a semiconductor layer, e.g., a CMOS layer, using a bonding layer 726, thereby forming a MEMS device. In this example, the semiconductor layer may include a structure 300L, 400H, 500J, or 600G as described above with a bumpstop 732 with a step shape form to reduce stiction. The structure 300L, 400H, 500J, or 600G may also include electrode 734 (corresponding to the stacked metal layer 344) and also outgassing stack 738 (corresponding to the region associated with the stacked metal layer 342). It is appreciated that the outgassing layer is present for the accel cavity 742 to control the pressure within the cavity while it is absent from the gyro cavity 744.

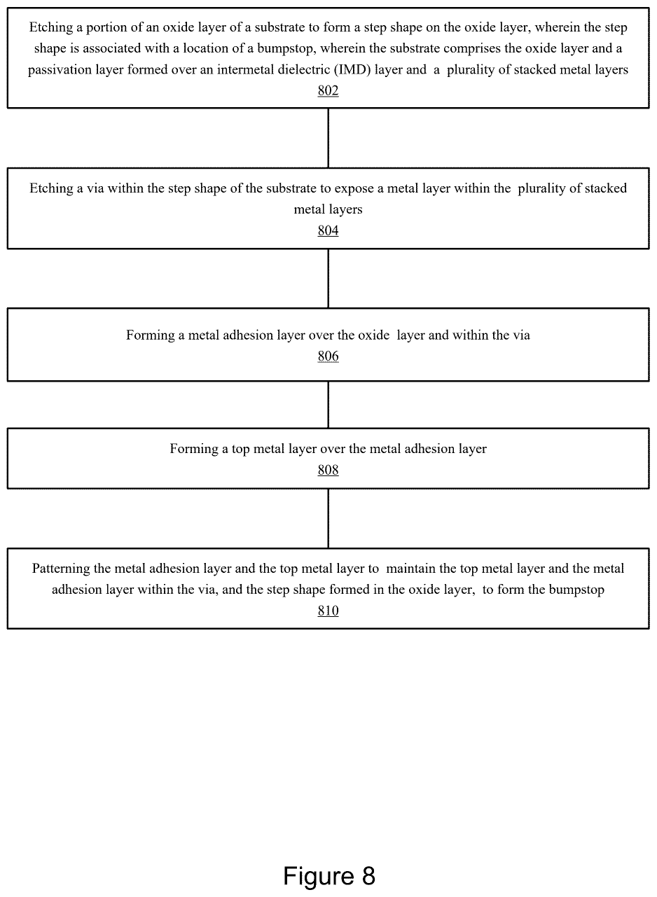

FIG. 8 shows a flow diagram for forming a bumpstop according to one aspect of the present embodiments. At step 802, a portion of an oxide layer of a substrate is etched to form a step shape on the oxide layer, as described above. The step shape is associated with a location of a bumpstop, as described above. According to some embodiments, the substrate includes the oxide layer and a passivation layer formed over an IMD layer and a plurality of stacked metal layers, as described above. At step 804, a via is etched within the step shape of the substrate to expose a metal layer within the plurality of stacked metal layers, as described above. At step 806, a metal adhesion layer is formed over the oxide layer and within the via, as described above. At step 808, a top metal layer is formed over the metal adhesion layer, as described above. At step 810, the metal adhesion layer and the top metal layer are patterned to maintain the top metal layer and the metal adhesion layer within the via, and the step shape formed in the oxide layer, to form the bumpstop, as described above.

While the embodiments have been described and/or illustrated by means of particular examples, and while these embodiments and/or examples have been described in considerable detail, it is not the intention of the Applicants to restrict or in any way limit the scope of the embodiments to such detail. Additional adaptations and/or modifications of the embodiments may readily appear, and, in its broader aspects, the embodiments may encompass these adaptations and/or modifications. Accordingly, departures may be made from the foregoing embodiments and/or examples without departing from the scope of the concepts described herein. The implementations described above and other implementations are within the scope of the following claims.

What is claimed is:

1. A method comprising:
etching a portion of an oxide layer of a substrate to form a step shape on the oxide layer, wherein the step shape is associated with a location of a bumpstop,
wherein the substrate comprises the oxide layer and a passivation layer formed over an intermetal dielectric (IMD) layer and a plurality of stacked metal layers;
etching a via within the step shape of the substrate to expose a metal layer within the plurality of stacked metal layers;
forming a metal adhesion layer over the oxide layer and within the via;
forming a top metal layer over the metal adhesion layer; and
patterning the metal adhesion layer and the top metal layer to maintain the top metal layer and the metal adhesion layer within the via, and top of the step shape formed in the oxide layer, to form the bumpstop.

2. The method of claim 1, wherein the patterning further comprises patterning to retain the metal adhesion layer and top metal layer over the vertical side wall of the step shape.

3. The method of claim 1, wherein the patterning further comprises exposing a portion of the oxide layer on the bumpstop.

4. The method of claim 3, further comprising etching the exposed oxide layer to form a second step shape and patterning to retain the metal adhesion layer and the top metal layer over the second step.

5. The method of claim 1, wherein the metal adhesion layer is selected from a group consisting of Titanium (Ti), Tantalum (Ta), and chromium.

6. The method of claim 1, wherein the top metal layer is selected from a group consisting of Titanium Nitride (TiN), Titanium Tungsten (TiW), and Tantalum Nitride (TaN).

7. The method of claim 1 further comprising:
etching a second portion of the substrate to expose an outgassing layer within the oxide layer.

8. The method of claim 7, wherein the etching the portion of the oxide layer of a substrate further comprises etching the oxide layer over the second portion of the substrate and retain a portion of the oxide layer over the outgassing layer.

9. The method of claim 1 further comprising etching a third portion of the substrate to expose a second plurality of stacked metal layers.

10. The method of claim 1 further comprising forming a dimple pattern in the oxide layer prior to etching the via.

11. The method of claim 10 further comprising forming the metal adhesion layer and the top metal layers conforming the dimple pattern.

12. A device comprising:
a substrate comprising an oxide layer, a passivation layer and an intermetal dielectric (IMD) layer;
a first region of the substrate is associated with a bumpstop; and
wherein the bumpstop comprises a step in the oxide layer, and
wherein the bumpstop includes a via formed within the oxide layer and further within the passivation layer and reaches a metal layer of a plurality of stacked metal layers, and
wherein a metal adhesion layer is formed over a top horizontal portion of the step in the oxide layer and further within the via, and wherein a top metal layer is formed over the metal adhesion layer.

13. The device of claim 12, wherein the metal-adhesion layer and the top metal layer covers the vertical side wall of the step.

14. The device of claim 12, wherein the metal-adhesion layer and the top metal layer covers a lowers horizontal layer of the step.

15. The device of claim 14, further comprising a second step in the oxide layer in the outer periphery of the bumpstop.

16. The device of claim 12, wherein the metal adhesion layer is selected from a group consisting of Titanium (Ti), Tantalum (Ta), and chromium.

17. The device of claim 12, wherein the top metal layer is selected from a group consisting of Titanium Nitride (TiN), Titanium Tungsten (TiW), and Tantalum Nitride (TaN).

18. The device of claim 17, wherein a top surface of the oxide layer of the bumpstop has a plurality of dimples, and wherein the metal-adhesion layer and the top metal layer trace contours of the plurality of dimples.

19. The device of claim 12, further comprising a second region of the substrate, wherein an outgassing layer is disposed within the oxide layer.

20. The device of claim 12, wherein a second plurality of stacked metal layers is disposed over the passivation layer in the third region.
